(19) United States
(12) Patent Application Publication
(10) Pub. No.: US 2026/0344474 A1
(43) Pub. Date: Oct. 29, 2026

(54) SEMICONDUCTOR DEVICE AND ELECTRONIC APPARATUS

(71) Applicant: FUJI ELECTRIC CO., LTD., Kawasaki-shi (JP)

(72) Inventors: Yuji IIZUKA, Matsumoto-city (JP); Kensuke MATSUZAWA, Matsumoto-city (JP)

(73) Assignee: FUJI ELECTRIC CO., LTD., Kawasaki-shi (JP)

(21) Appl. No.: 19/631,697

(22) Filed: Mar. 27, 2026

(30) Foreign Application Priority Data
Apr. 25, 2025 (JP) 2025-073061

(51) Int. Cl. H10W 70/65; H10W 40/20; H10W 74/10; H10W 90/00

(52) U.S. Cl. CPC H10W 70/65; H10W 40/235; H10W 74/111; H10W 90/401

(57) ABSTRACT

A semiconductor device includes a resin sealing body having a first surface and a second surface opposed to each other to seal the insulated circuit substrate, the first and second semiconductor chips, and the wired substrate in a state in which the respective top surfaces of the first, second, and third conductive pads are exposed outward through the first surface, and the cooling plate is exposed outward through the second surface.

### CROSS-REFERENCE TO RELATED APPLICATION

This application claims benefit of priority under 35 USC 119 based on Japanese Patent Application No. 2025-073061 filed on Apr. 25, 2025, the entire contents of which are incorporated by reference herein.

### BACKGROUND OF THE INVENTION

### 1. Field of the Invention

The present technology (the technology according to the present disclosure) relates to semiconductor devices and electronic apparatuses, and particularly to a semiconductor device having a cooling plate, and an electronic apparatus including the same.

### 2. Description of the Related Art

The following are the art related to the present technology.

JP2020-043102A discloses a semiconductor device installed in an electric power conversion apparatus, the semiconductor device including a metal base plate (a cooling plate) exposed outward through a bottom surface of a case (a sealing body) in a thickness direction. JP2020-043102A also discloses that copper inlays are inserted into through-holes of a relay substrate in order to enhance current density.

JP2023-183805A discloses that inlays made of metal pillars are inserted into through-holes penetrating a main circuit printed substrate so as to enhance heat-releasing performance of the main circuit printed substrate.

JP2003-324176A discloses a semiconductor power module in which leads serving as external terminals laterally project from a side surface of a molded resin (a resin sealing body).

Conventional electric power conversion apparatuses have a configuration in which a cooling plate of a semiconductor device is connected to a heat sink via heat-conductive material.

In a case of using a semiconductor device in which a cooling plate projects from a bottom surface of a resin sealing body, it is necessary to ensure a creepage distance along a surface of the resin sealing body between an external terminal and the cooling plate of the semiconductor device in order to increase dielectric strength, since such an electric power conversion apparatus typically uses high voltage. In a case of using a semiconductor device in which a bottom surface of a resin sealing body and a bottom surface of a cooling plate are level with each other, it is necessary to ensure a creepage distance along a surface of the resin sealing body between an external terminal and a heat sink of the semiconductor device in order to increase dielectric strength.

In a case in which leads serving as external terminals project from a side surface of the resin sealing body, however, the creepage distance between the external terminals (the leads) and the cooling plate or the heat sink is decreased, which impedes the provision of the creepage distance sufficient for electric power to be required.

While such a necessary creepage distance could be ensured such that a thickness of the resin sealing body is increased or a planar size of the resin sealing body is increased, a package size of the semiconductor device is also increased.

Another structure is also conventionally known in which lead pins serving as external terminals project from a top surface of the resin sealing body. When the resin sealing body is formed by transfer molding suitable for mass production in this case, however, such a structure complicates a design of a molding metal die to be used, or could lead to a reduction in yield rate because of resin leakage.

### SUMMARY OF THE INVENTION

In view of the foregoing problems, the present technology aims to provide a configuration capable of improving dielectric strength while avoiding an increase in size of a semiconductor device.

A semiconductor device according to an aspect of the present technology includes:
an insulated circuit substrate including a first conductive plate, a second conductive plate, and a third conductive plate on one surface, and a cooling plate on another surface opposite to the one surface;
a first semiconductor chip having a main surface and a rear surface opposed to each other each provided with an electrode, the electrode of the rear surface being connected to the first conductive plate;
a second semiconductor chip having a main surface and a rear surface opposed to each other each provided with an electrode, the electrode of the rear surface being connected to the third conductive plate;
a wired substrate provided toward the one surface of the insulated circuit substrate so as to be arranged separately from the respective first and second semiconductor chips, and including a first wiring part electrically connected to the electrode of the main surface of the first semiconductor chip and a second wiring part electrically connected to the electrode of the main surface of the second semiconductor chip;
a first conductive pad provided toward the one surface of the insulated circuit substrate so as to be connected to the first conductive plate, and having a flat top surface;
a second conductive pad provided toward the one surface of the insulated circuit substrate so as to be connected to the second conductive plate, and having a flat top surface;
a third conductive pad provided toward the one surface of the insulated circuit substrate so as to be connected to the third conductive plate, and having a flat top surface;
a first conductive member connected to each of the first wiring part and the third conductive plate;
a second conductive member connected to each of the second wiring part and the second conductive plate; and
a resin sealing body having a first surface and a second surface opposed to each other to seal the insulated circuit substrate, the first and second semiconductor chips, and the wired substrate in a state in which the respective top surfaces of the first, second, and third conductive pads are exposed outward through the first surface, and the cooling plate is exposed outward through the second surface.

The respective top surfaces of the first, second, and third conductive pads may be positioned closer to the first surface of the resin sealing body than the wired substrate.

The first, second, and third conductive pads each may have a greater thickness than the wired substrate.

The first, second, and third conductive pads may be each directly fixed to the insulated circuit substrate.

The respective top surfaces of the first, second, and third conductive pads may have a middle region exposed outward from the resin sealing body, and an outer edge region surrounding the middle region and covered with the resin sealing body.

The first and second wiring parts may be stacked on the insulating plate.

Heights of the respective top surfaces of the first, second, and third conductive pads from the insulated circuit substrate may be common to each other.

Heights of the respective top surfaces of the first and second conductive pads from the insulated circuit substrate may be different from each other.

The semiconductor device may further include a positioning member for aligning the insulated circuit substrate and the wired substrate in relative position, wherein the wired substrate may be supported on the insulated circuit substrate via the positioning member and the respective first and second conductive members.

An electronic apparatus according to an aspect of the present technology including a heat sink and a plurality of semiconductor devices mounted on the heat sink.

The respective semiconductor devices include:
an insulated circuit substrate including a first conductive plate, a second conductive plate, and a third conductive plate on one surface, and a cooling plate on another surface opposite to the one surface;
a first semiconductor chip having a main surface and a rear surface opposed to each other each provided with an electrode, the electrode of the rear surface being connected to the first conductive plate;
a second semiconductor chip having a main surface and a rear surface opposed to each other each provided with an electrode, the electrode of the rear surface being connected to the third conductive plate;
a wired substrate provided toward the one surface of the insulated circuit substrate so as to be arranged separately from the respective first and second semiconductor chips, and including a first wiring part electrically connected to the electrode of the main surface of the first semiconductor chip and a second wiring part electrically connected to the electrode of the main surface of the second semiconductor chip;
a first conductive pad provided toward the one surface of the insulated circuit substrate so as to be connected to the first conductive plate, and having a flat top surface;
a second conductive pad provided toward the one surface of the insulated circuit substrate so as to be connected to the second conductive plate, and having a flat top surface;
a third conductive pad provided toward the one surface of the insulated circuit substrate so as to be connected to the third conductive plate, and having a flat top surface;
a first conductive member connected to each of the first wiring part and the third conductive plate;
a second conductive member connected to each of the second wiring part and the second conductive plate; and
a resin sealing body having a first surface and a second surface opposed to each other to seal the insulated circuit substrate, the first and second semiconductor chips, and the wired substrate in a state in which the respective top surfaces of the first, second, and third conductive pads are exposed outward through the first surface, and the cooling plate is exposed outward through the second surface.

The cooling plate on one side on an opposite side of a surface toward the resin sealing body in the respective semiconductor devices may be connected to the heat sink with a heat-conductive material layer interposed.

The electronic apparatus may further include: a capacitor unit including a positive-electrode terminal and a negative-electrode terminal; and a relay substrate electrically connecting the respective semiconductor device and the capacitor unit to each other, wherein the relay substrate may include an insulating plate, a positive-electrode conductive plate provided on one surface of the insulating plate and electrically connected to each of the positive-electrode terminal of the capacitor unit and the first conductive pad of the respective semiconductor devices, and a negative-electrode conductive plate provided on an opposite side of the one surface of the insulating plate and electrically connected to each of the negative-electrode terminal of the capacitor unit and the second conductive pad of the respective semiconductor devices.

It should be noted that the above summary of the invention does not list all the necessary features of the present invention. Subcombinations of these feature groups can also be inventions.

### BRIEF DESCRIPTION OF THE DRAWINGS

FIG. 1 is an equivalent circuit diagram illustrating a semiconductor device according to a first embodiment of the present technology;

FIG. 2 is a plan view schematically illustrating an external structure of the semiconductor device in FIG. 1;

FIG. 3A is a plan view schematically illustrating an internal structure of the semiconductor device in FIG. 1;

FIG. 3B is a plan view illustrating the semiconductor device while omitting the illustration of a wired substrate in FIG. 3A;

FIG. 3C is a plan view added with diagonal lines in the wired substrate in FIG. 3A;

FIG. 4 is a vertical cross-sectional view schematically illustrating a vertical cross-sectional structure taken along line IV-IV in FIG. 3A;

FIG. 5 is a partly-enlarged vertical cross-sectional view illustrating a main part in FIG. 4;

FIG. 6 is a vertical cross-sectional view schematically illustrating a vertical cross-sectional structure taken along line VI-VI in FIG. 3A;

FIG. 7 is a partly-enlarged vertical cross-sectional view illustrating a main part in FIG. 6;

FIG. 8 is a vertical cross-sectional view schematically illustrating a vertical cross-sectional structure taken along line VIII-VIII in FIG. 3A;

FIG. 9 is a vertical cross-sectional view schematically illustrating a vertical cross-sectional structure taken along line IX-IX in FIG. 3A;

FIG. 10 is a plan view schematically illustrating a structure of an assembled member used for a method of manufacturing the semiconductor device according to the first embodiment of the present technology;

FIG. 11 is a vertical cross-sectional view schematically illustrating a vertical cross-sectional structure taken along line XI-XI in FIG. 10;

FIG. 12 is a vertical cross-sectional view schematically illustrating a vertical cross-sectional structure of a molding metal die used for the method of manufacturing the semiconductor device according to the first embodiment of the present technology;

FIG. 13 is a vertical cross-sectional view schematically illustrating a process of the method of manufacturing the semiconductor device according to the first embodiment of the present technology;

FIG. 14 is a vertical cross-sectional view schematically illustrating the process continued from FIG. 13;

FIG. 15 is an equivalent circuit diagram illustrating a power conversion apparatus including three semiconductor devices as illustrated in FIG. 1;

FIG. 16 is a plan view schematically illustrating a structure of the power conversion apparatus in FIG. 15;

FIG. 17 is a main vertical cross-sectional view schematically illustrating a vertical cross-sectional structure taken along line XVII-XVII in FIG. 16;

FIG. 18 is a main vertical cross-sectional view schematically illustrating a vertical cross-sectional structure taken along line XVIII-XVIII in FIG. 16;

FIG. 19 is a view showing a creepage distance in the semiconductor device according to the first embodiment in a case in which a cooling plate projects from a bottom surface of a resin sealing body;

FIG. 20 is a view showing a creepage distance in the semiconductor device according to the first embodiment in a case in which the bottom surface of the resin sealing body and a bottom surface of the cooling plate are level with each other;

FIG. 21 is a view showing a creepage distance in a conventional semiconductor device of a referential example when a lead projects from a side surface of a resin sealing body and a cooling plate projects from a bottom surface of the resin sealing body;

FIG. 22 is a view showing a creepage distance in the conventional semiconductor device of the referential example when the lead projects from the side surface of the resin sealing body and the bottom surface of the resin sealing body and a bottom surface of the cooling plate are level with each other;

FIG. 23 is a plan view schematically illustrating an internal structure of a semiconductor device according to modified example 1-1 of the first embodiment of the present technology; and

FIG. 24 is a vertical cross-sectional view schematically illustrating a vertical cross-sectional structure of a semiconductor device according to modified example 1-2 of the first embodiment of the present technology.

### DETAILED DESCRIPTION

Hereinafter, an embodiment of the present technology is described in detail with reference to the drawings.

In the following explanations of the drawings, the same or similar components are denoted by the same or similar reference numerals. It should be noted that the drawings are schematic illustrations, and the relations between thicknesses and planar dimensions, or the proportions of thicknesses of layers illustrated below are not drawn to scale. The specific thicknesses or dimensions of the components thus should be considered as appropriate in accordance with the corresponding explanations as made below.

It should also be noted that the relations or proportions of the dimensions between the respective drawings can differ from each other. In addition, the effects described herein are not limited to those as illustrated, and any other effects can be achieved by the present technology.

The embodiment described below illustrates devices and methods for embodying the technical idea of the present technology, which is not intended to limit structures to those as disclosed herein. The technical idea of the present technology thus can include various modifications within a range of the subject matter according to the appended claims.

In the following explanations, the directional definitions such as "top", "bottom", “upper-lower”, “left”, “right”, and “right-left” are made simply for illustration purposes, and are not intended to limit the technical idea of the present technology. For example, when an orientation of a target is turned by 90 degrees, the "upper-lower" direction should be changed to the "right-left" direction, and when the orientation of the target is turned by 180 degrees, the “upper-lower" direction should be reversed.

The terms “top surface” and “bottom surface” used in the following explanations may be changed to the terms “front surface” and “rear surface”. The terms “first main surface” and “second main surface” used for components described below are corresponding main surfaces opposed to each other. For example, when the “first main surface” is defined as a top surface, the “second main surface” is then defined as a bottom surface. Further, the “first main surface” and the “second main surface” as used herein can also be referred to as “one main surface” and “another main surface” respectively.

The following embodiment defines three directions perpendicular to each other in a common space, in which a first direction and a second direction are referred to as an X direction and a Y direction perpendicular to each other in the same plane, and a third direction perpendicular to each of the first direction and the second direction is referred to as a Z direction. A stacking direction in which an insulated circuit substrate and a wired substrate as described below are stacked together is defined as the Z direction in the following embodiment.

When a transistor installed in a semiconductor chip as used herein is a field-effect transistor (FET), a static induction transistor (SIT), or the like, a first main electrode is referred to as either a source electrode or a drain electrode, a second main electrode is referred to as the other one of the electrodes, and a control electrode is referred to as a gate electrode. When a transistor installed in a semiconductor chip is a bipolar junction transistor (BJT) or the like, a first main electrode is referred to as either an emitter electrode or a collector electrode, a second main electrode is referred to as the other one of the electrodes, and a control electrode is referred to as a base electrode. When a transistor installed in a semiconductor chip is an insulated gate bipolar transistor (IGBT) or the like, a first main electrode is referred to as either an emitter electrode or a collector electrode, a second main electrode is referred to as the other one of the electrodes, and a control electrode is referred to as a gate electrode. The following embodiment illustrates a transistor installed in a semiconductor chip with a MISFET, which is one of insulated gate field-effect transistors, in which a first main electrode is referred to as a source electrode, a second main electrode is referred to as a drain electrode, and a control electrode is referred to as a gate electrode.

Further, the following embodiment illustrates a case in which a planar view is defined such that an electronic apparatus is viewed in the Z direction. The embodiment also illustrates a case in which a vertical cross-sectional view is defined such that a cross section of the electronic apparatus in the Z direction is viewed in a direction perpendicular to the Z direction.

### FIRST EMBODIMENT

A first embodiment is illustrated below with an example in which the present technology is applied to a semiconductor device (a power semiconductor device) used as a constituent member in a power conversion apparatus.

The first embodiment is also illustrated with a semiconductor device of package type including two elements (a 2-in-1 semiconductor device). The 2-in-1 semiconductor device includes two sets of elements each including a semiconductor switching element and a rectification element.

### ENTIRE CONFIGURATION OF SEMICONDUCTOR DEVICE

An entire configuration of the semiconductor device is described below.

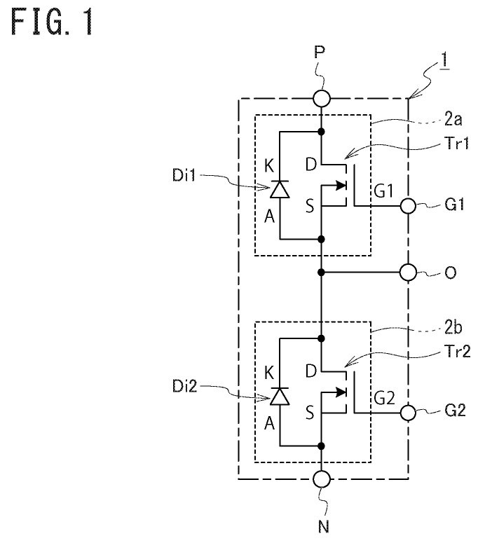

As illustrated in FIG. 1, the semiconductor device 1 according to the first embodiment of the present technology includes a switching element Tr1 serving as an upper arm 2a, a rectification element Di1 connected antiparallel to the switching element Tr1, a switching element Tr2 serving as a lower arm 2b, and a rectification element Di2 connected antiparallel to the switching element Tr2. The switching element Tr1 and the switching element Tr2 are connected in series.

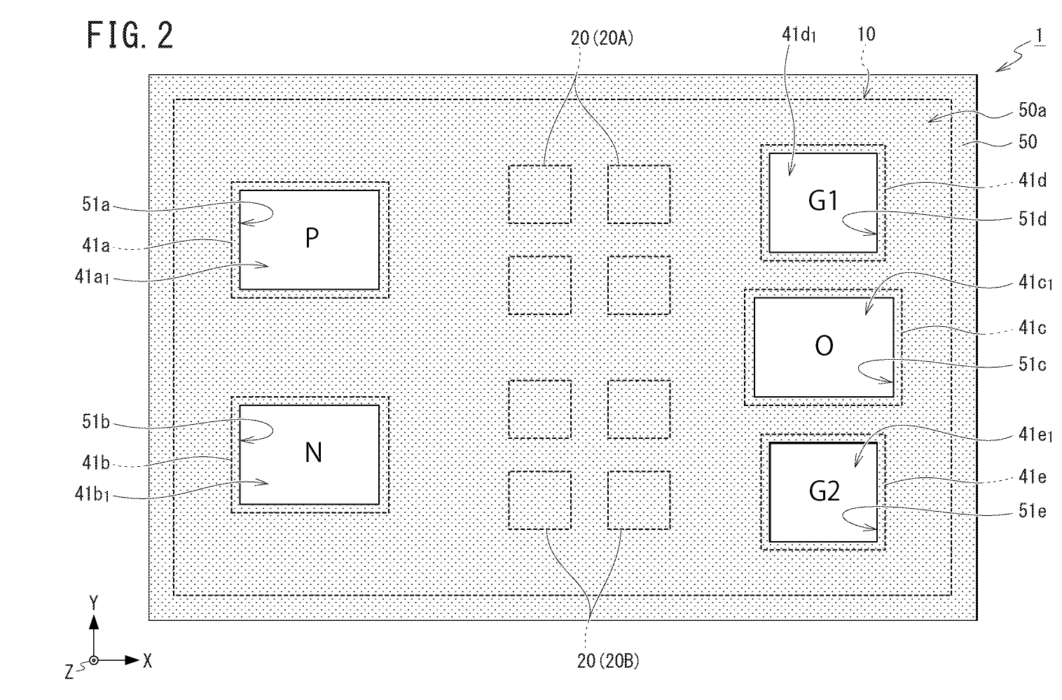

The semiconductor device 1 according to the first embodiment of the present technology also includes a positive-electrode terminal P, a negative-electrode terminal N, an output terminal O, a first control terminal G1, and a second control terminal G2. The positive-electrode terminal P corresponds to a first conductive pad 41a (refer to FIG. 2) described below. The negative-electrode terminal N corresponds to a second conductive pad 41b (refer to FIG. 2) described below. The output terminal O corresponds to a third conductive pad 41c (refer to FIG. 2) described below. The first control terminal G1 corresponds to a fourth conductive pad 41d (refer to FIG. 2) described below. The second control terminal G2 corresponds to a fifth conductive pad 41e (refer to FIG. 2) described below.

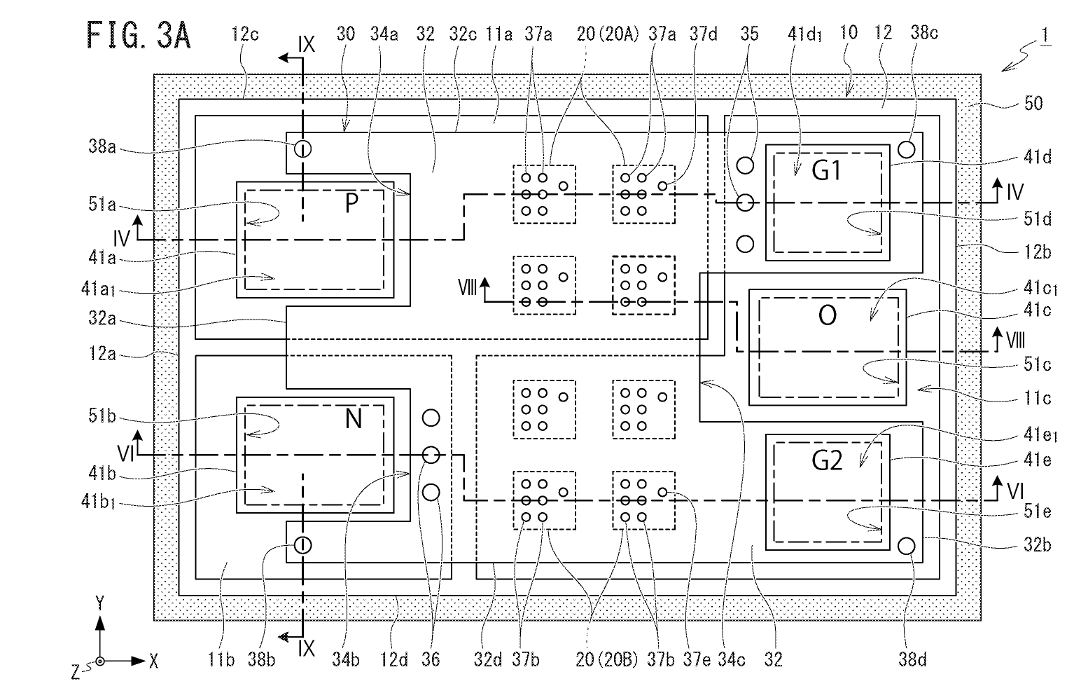

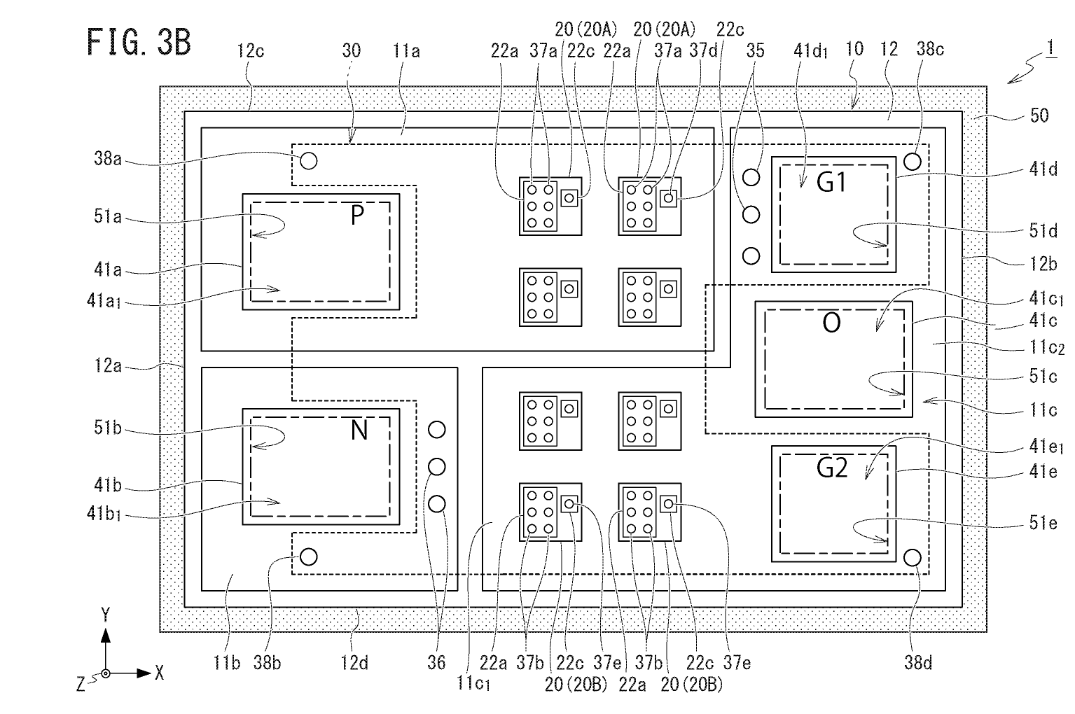

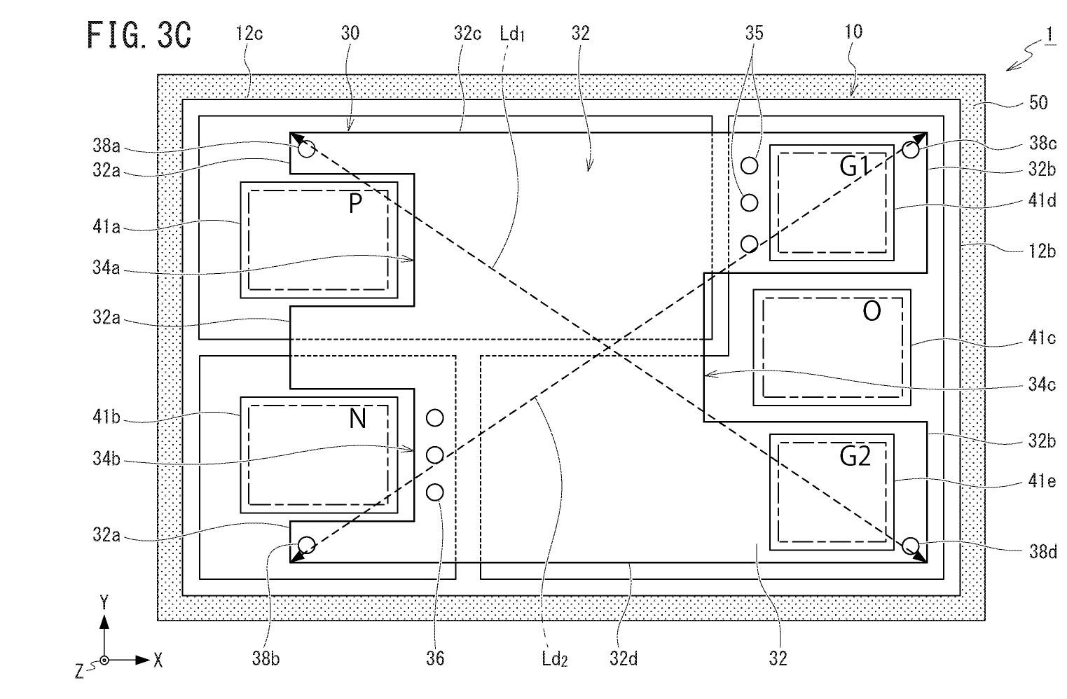

The switching element Tr1, although not limited to this case, includes transistors installed in a plurality of semiconductor chips 20A illustrated in FIG. 3B to be connected in parallel so as to achieve an increase in current capacity, for example. The switching element Tr2 also includes transistors installed in a plurality of semiconductor chips 20B illustrated in FIG. 3B to be connected in parallel so as to achieve an increase in current capacity, as in the case of the switching element Tr1. The respective transistors as used herein are preferably a vertical semiconductor element having an insulated gate structure, such as a metal-insulator-semiconductor field-effect transistor (MISFET), an insulated gate bipolar transistor (IGBT), and a reverse-conductive IGBT (RC-IGBT), through which main current flows in a depth direction (a thickness direction) of the semiconductor chips 20 (20A, 20B). The first embodiment illustrates a case of using a vertical MISFET, for the respective switching elements Tr1 and Tr2, having an insulated gate structure mainly including a semiconductor substrate of silicon carbide (SiC).

The rectification element Di1, although not limited to this case, includes diodes installed in the respective first semiconductor chips 20A illustrated in FIG. 3B to be connected in parallel so as to achieve an increase in current capacity, for example. The rectification element Di2 also includes diodes installed in the respective second semiconductor chips 20B illustrated in FIG. 3B to be connected in parallel so as to achieve an increase in current capacity, as in the case of the rectification element Di1. The diodes as used herein can be vertical freewheeling diodes (FWDs), for example. A body diode can be used as a FWD.

As illustrated in FIG. 1, the switching element Tr1 is configured such that a first main electrode (a source electrode) S is electrically connected to each of a second main electrode (a drain electrode) D of the switching element Tr2 and the output terminal O, and the second main electrode (the drain electrode) D is electrically connected to the positive-electrode terminal P. A control electrode (a gate electrode) G of the switching element Tr1 is electrically connected to the first control terminal G1.

As illustrated in FIG. 1, the switching element Tr2 is configured such that a first main electrode (a source electrode) S is electrically connected to the negative-electrode terminal N, and a second main electrode (a drain electrode) D is electrically connected to each of the first main electrode (the source electrode) S of the switching element Tr1 and the output terminal O. A control electrode (a gate electrode) G of the switching element Tr2 is electrically connected to the second control terminal G2.

As illustrated in FIG. 1, the rectification element Di1 is configured such that an anode electrode A is electrically connected to the first main electrode (the source electrode) S of the switching element Tr1, and a cathode electrode K is electrically connected to the second main electrode (the drain electrode) D of the switching element Tr1. Similarly, the rectification element Di2 is configured such that an anode electrode A is electrically connected to the first main electrode (the source electrode) S of the switching element Tr2, and a cathode electrode K is electrically connected to the second main electrode (the drain electrode) D of the switching element Tr2.

The MISFET installed in the respective semiconductor chips 20 (20A and 20B) encompasses a general idea including a MOSFET and a MISSIT. While a MOSFET typically uses a silicon oxide film (a SiO₂ film) as a gate insulating film, the MISFET is referred to as a more general insulated gate transistor using an insulating film, other than a silicon oxide film, as a gate insulating film.

Examples of gate insulating films used for such a MISFET can be a silicon oxynitride (SiON) film, a strontium oxide (SrO) film, a silicon nitride (Si₃N₄) film, or an aluminum oxide (Al₂O₃) film. Other examples include a magnesium oxide (MgO) film, an yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film. Alternatively, a composite film including some of the above single films selected and stacked on one another can also be used.

### SPECIFIC CONFIGURATION OF SEMICONDUCTOR DEVICE

A specific configuration of the semiconductor device 1 according to the first embodiment of the present technology is described below with reference to FIGS. 2-9.

FIG. 3A omits the illustration of a wiring pattern of a wired substrate 30.

As illustrated in FIGS. 2-9, the semiconductor device 1 according to the first embodiment includes an insulated circuit substrate 10, the first semiconductor chips 20A and the second semiconductor chips 20B installed on one surface side of the insulated circuit substrate 10, and the wired substrate 30 provided over the one surface of the insulated circuit substrate 10 separately from the first semiconductor chips 20A and the second semiconductor chips 20B.

The semiconductor device 1 according to the first embodiment also includes a first conductive pad 41a, a second conductive pad 41b, and a third conductive pad 41c fixed on the one surface side of the insulated circuit substrate 10, and a fourth conductive pad 41d and a fifth conductive pad 41e provided in the wired substrate 30.

The semiconductor device 1 according to the first embodiment also includes first conductive members 35 and second conductive members 36, conductive pins 37a, conductive pins 37b, conductive pin 37d, and conductive pins 37e, and a resin sealing body 50.

The semiconductor device 1 according to the first embodiment further includes positioning pins 38a to 38d serving as positioning members for aligning the insulated circuit substrate 10 and the wired substrate 30 in relative position.

### Insulated Circuit Substrate

As illustrated in FIGS. 3A-9, the insulated circuit substrate 10 includes an insulating plate 12, a first conductive plate 11a, a second conductive plate 11b, and a third conductive plate 11c provided to be level with each other on one surface side of the insulating plate 12, and a cooling plate 13 provided on the other side opposite to the one surface side of the insulating plate 12. Namely, the semiconductor device 1 according to the first embodiment includes the insulated circuit substrate 10 including the first, second, and third conductive plates 11a, 11b, and 11c on one surface, and the cooling plate 13 on the other surface opposite to the one surface.

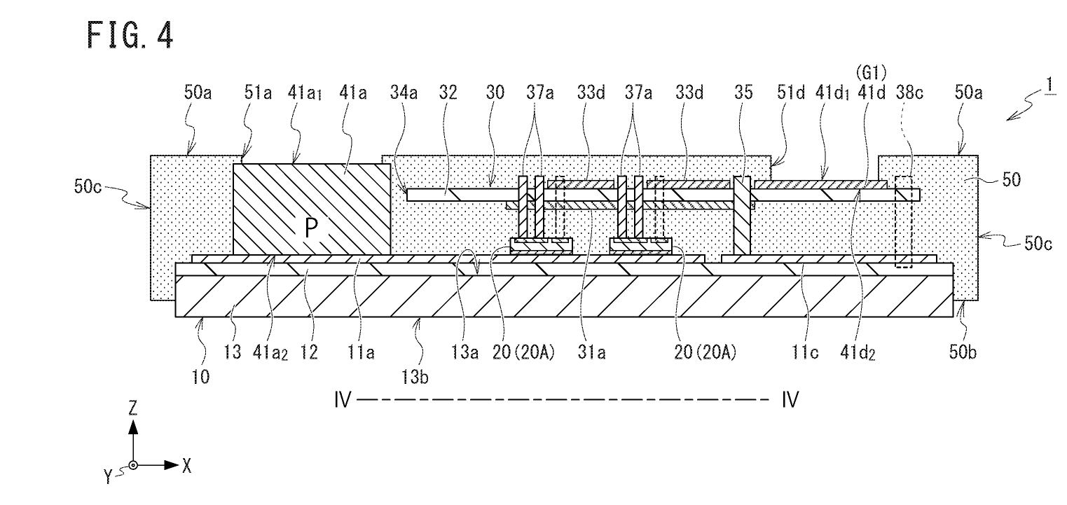

As illustrated in FIGS. 3A and 3B, the insulated circuit substrate 10 has a rectangular, particularly oblong shape in the planar view, for example. The insulated circuit substrate 10 has two short sides opposed to each other in the X direction (the longitudinal direction) and extending in the Y direction (the short-side direction) perpendicular to the X direction, and two long sides opposed to each other in the Y direction and extending in the X direction. The insulated circuit substrate 10 has a thickness in the Z direction perpendicular to the X direction and the Y direction, as illustrated in FIGS. 4-9.

The insulated circuit substrate 10 as used herein can be a direct copper bonded (DCB) substrate obtained such that a top surface and a bottom surface of a ceramic substrate opposed to each other are each subjected to eutectic bonding with metal, or an active metal brazed (AMB) substrate obtained such that metal is applied to each of a top surface and a bottom surface of a ceramic substrate opposed to each other by active metal brazing (AMB), for example. Examples of material used for such a ceramic substrate include silicon nitride (Si₃N₄), aluminum nitride (AlN), alumina (Al₂O₃). The insulated circuit substrate 10 in the first embodiment includes an aluminum nitride plate used as the insulating plate 12, and a metal plate including copper (Cu), having high electric and heat conductive properties, used as the respective conductive plates (the first to third conductive plates 11a, 11b, and 11c) and the cooling plate 13. Alternatively, the insulating plate 12 as used herein may be a substrate including glass fiber and impregnated with insulating polymer such as epoxy resin, a substrate in which inorganic filler such as boron nitride (BN) and aluminum nitride (AlN) is added to insulating polymer such as epoxy resin, or a substrate in which a surface of a flat-shaped metal core is coated with insulating polymer to which inorganic filler is added.

### Insulating Plate

As illustrated in FIGS. 3A and 3B, the insulating plate 12 has a rectangular, particularly oblong shape in the planar view, for example. The insulating plate 12 has a top surface (one surface) and a bottom surface (a rear surface opposite to the one surface) opposed to each other in the Z direction which is a thickness direction. The insulating plate 12 includes two short sides 12a and 12b opposed to each other in the X direction and extending in the Y direction perpendicular to the X direction, and two long sides 12c and 12d opposed to each other in the Y direction and extending in the X direction. The first embodiment illustrates a case in which the two short sides 12a and 12b of the insulating plate 12 correspond to the two short sides of the insulated circuit substrate 10, and the two long sides 12c and 12d of the insulating plate 12 correspond to the two long sides of the insulated circuit substrate 10.

### Conductive Plate

As illustrated in FIG. 3B, the first conductive plate 11a is located toward the short side 12a which is one of the two short sides 12a and 12b of the insulating plate 12 and also toward the long side 12c which is one of the two the long sides 12c and 12d of the insulating plate 12 in the planar view. The first conductive plate 11a extends from the short side 12a on one side toward the other short side 12b of the insulating plate 12, and has a rectangular shape in the planar view.

As illustrated in FIG. 3B, the second conductive plate 11b is located toward the short side 12a which is one of the two short sides 12a and 12b of the insulating plate 12 and also toward the other long side 12d of the insulating plate 12 in the planar view. The second conductive plate 11b extends from the short side 12a on one side toward the other short side 12b of the insulating plate 12, and has a rectangular shape in the planar view. The second conductive plate 11b is aligned with the first conductive plate 11a separately with a predetermined gap provided in the Y direction, and has a shorter length in the X direction than the first conductive plate 11a.

As illustrated in FIG. 3B, the third conductive plate 11c has an L-shaped structure having a first part 11c₁ located toward the long side 12d which is one of the two long sides 12c and 12d of the insulating plate 12 in the planar view, and a second part 11c₂ integrated with the first part 11c₁ and extending between the long side 12c on one side and the other long side 12d of the insulating plate 12 in the planar view.

The first part 11c₁ of the third conductive plate 11c is aligned with the first conductive plate 11a separately with a predetermined gap provided in the Y direction and also aligned with the second conductive plate 11b separately with a predetermined gap provided in the X direction. The second part 11c₂ of the third conductive plate 11c is located next to the first conductive plate 11a separately with a predetermined gap provided in the X direction. The length of the second part 11c₂ in the Y direction is longer than the length of the first part 11c₁ in the X direction.

The respective first, second, and third conductive plates 11a, 11b, and 11c are separated from each other electrically and structurally (physically).

The first conductive plate 11a, the second conductive plate 11b, and the third conductive plate 11c described in the first embodiment correspond to specific examples of "a first conductive plate", "a second conductive plate", and "a third conductive plate" respectively according to the present technology.

### Cooling Plate

Although not illustrated in detail, the cooling plate 13 has a rectangular shape in the planar view, as in the case of the insulating plate 12, and has substantially the same planar size as the insulating plate 12. As illustrated in FIGS. 4-9, the cooling plate 13 is superposed on each of the first conductive plate 11a, the second conductive plate 11b, and the third conductive plate 11c with the insulating plate 12 interposed in the Z direction. The cooling plate 13, although not limited to this case, has a greater thickness than the respective first, second and third conductive plates 11a, 11b, and 11c.

### Semiconductor Chips

As illustrated in FIGS. 3B and 4, the first semiconductor chips 20A are provided on the first conductive plate 11a of the insulated circuit substrate 10. The number of the first semiconductor chips 20A is, although not limited to this case, four with a 2×2 array in the planar view, for example. The four first semiconductor chips 20A are located on the first conductive plate 11a in the middle part of the insulating plate 12 in the X direction in the planar view.

The transistors and the diodes with the vertical structure as described above are mounted on the respective first semiconductor chips 20A. The transistors mounted on the four first semiconductor chips 20A are connected in parallel to implement the switching element Tr1 illustrated in FIG. 1. The diodes mounted on the four first semiconductor chips 20A are connected in parallel to implement the rectification element Di1 illustrated in FIG. 1.

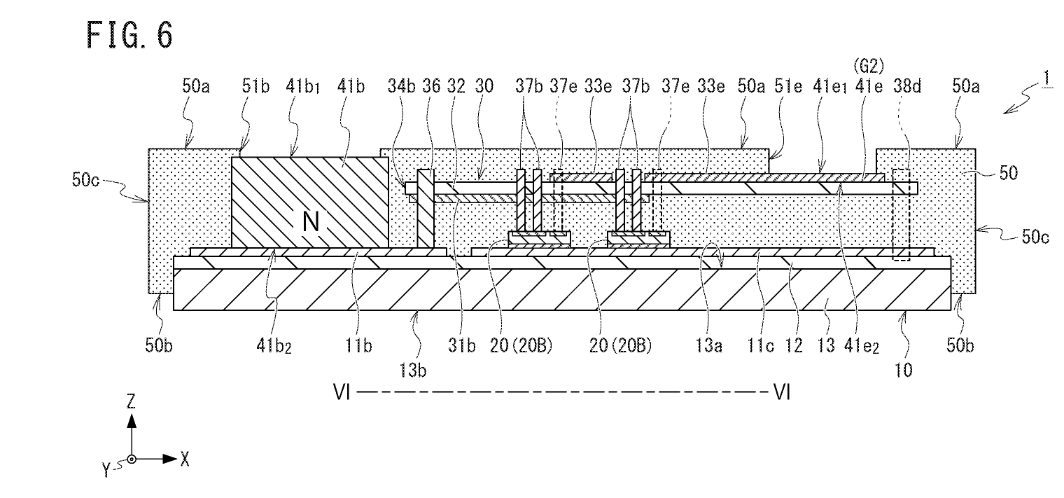

As illustrated in FIGS. 3B and 6, the second semiconductor chips 20B are provided on the third conductive plate 11c (the first part 11c₁) of the insulated circuit substrate 10. The number of the second semiconductor chips 20B is, although not limited to this case, four with a 2×2 array in the planar view, as in the case of the first semiconductor chips 20A. The four second semiconductor chips 20B are located on the third conductive plate 11c in the middle part of the insulating plate 12 in the X direction in the planar view.

The transistors and the diodes with the vertical structure as described above are mounted on the respective second semiconductor chips 20B. The transistors mounted on the four second semiconductor chips 20B are connected in parallel to implement the switching element Tr2 illustrated in FIG. 1. The diodes mounted on the four second semiconductor chips 20B are connected in parallel to implement the rectification element Di2 illustrated in FIG. 1.

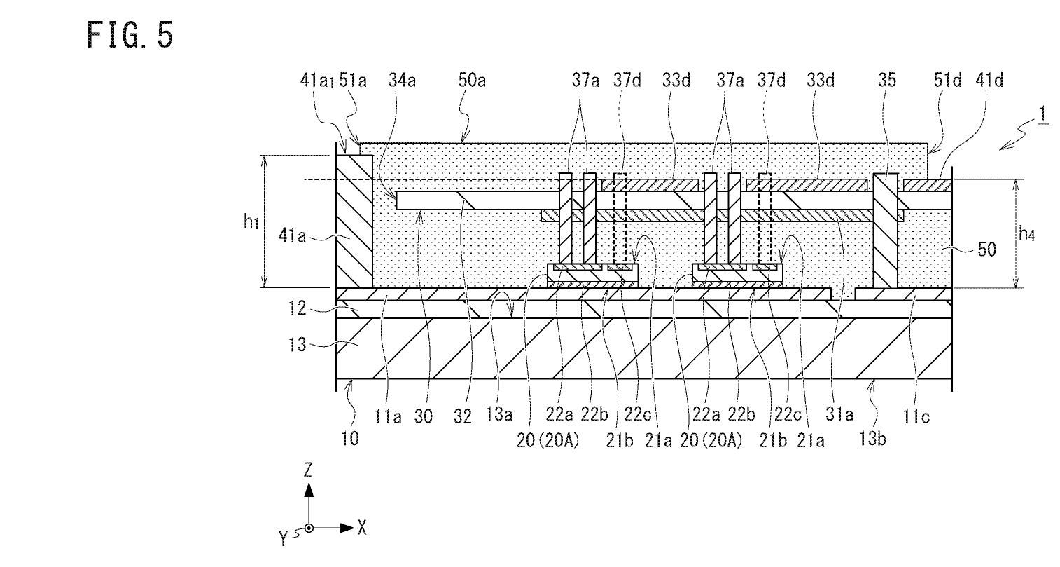

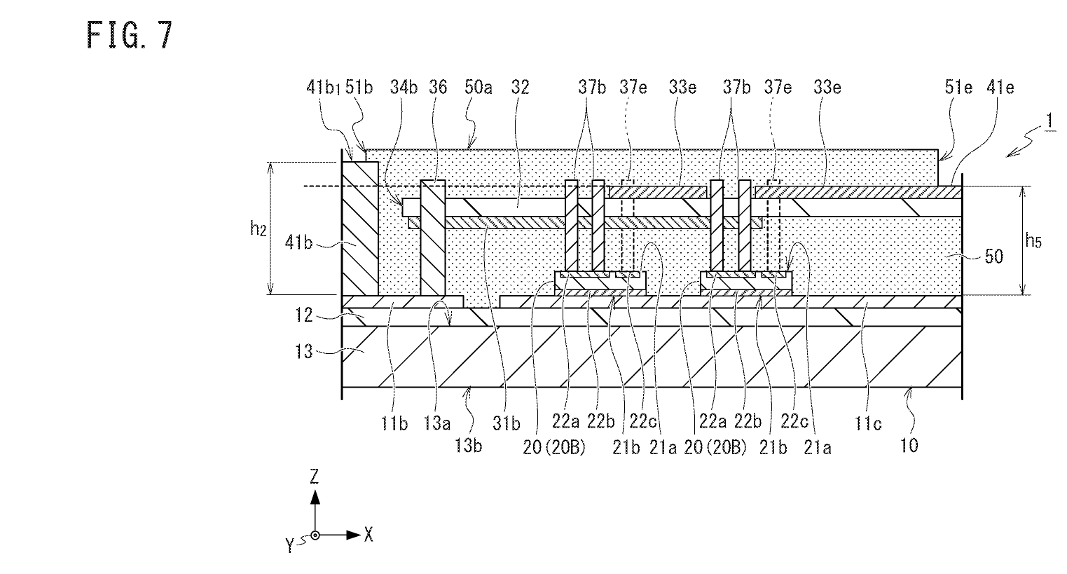

The four first semiconductor chips 20A and the four second semiconductor chips 20B have the same structure. In particular, as illustrated in FIGS. 5 and 7, the respective first semiconductor chips 20A and second semiconductor chips 20B each include a main surface 21a and a rear surface 21b opposed to each other, an electrode (a first main electrode) 22a and an electrode (a control electrode) 22c provided on the main surface 21a, and an electrode (a second main electrode) 22b provided toward the rear surface 21b side.

In the semiconductor chips 20 (20A and 20B) in the first embodiment, which use a MISFET for the respective transistors, the electrode 22a serves as a source electrode, the electrode 22b serves as a drain electrode, and the electrode 22c serves as a control electrode. A source region of the transistor and an anode region of the diode mounted on the respective semiconductor chips 20 (20A and 20B) are electrically connected to the electrode 22a. A drain region of the transistor and a cathode region of the diode mounted on the respective semiconductor chips 20 (20A and 20B) are electrically connected to the electrode 22b. A gate electrode of the transistor mounted on the respective semiconductor chips 20 (20A and 20B) is electrically connected to the electrode 22c. The electrode 22a and the electrode 22c are each made of an aluminum (Al) film or an alloy film mainly including Al. The electrode 22b is made of a copper (Cu) film or an alloy film mainly including Cu.

The four first semiconductor chips 20A and the four second semiconductor chips 20B each mainly include a substrate including wide bandgap semiconductor such as SiC and GaN, for example. The transistors and the diodes preferably have a vertical structure in which main current flows in the thickness direction (the depth direction: the Z direction) of the semiconductor chips 20 (20A and 20B).

While FIG. 5 only illustrates the two first semiconductor chips 20A, the four first semiconductor chips 20A each have a structure in which the electrode 22b toward the rear surface 21b is electrically and mechanically connected and bonded to the first conductive plate 11a via conductive bonding material (solder material, for example). The semiconductor device 1 according to the first embodiment thus includes the first semiconductor chips 20A each having the main surface 21a and the rear surface 21b provided with the respective electrodes (the main surface 21a provided with the electrodes 22a and 22c and the rear surface 21b provided with the electrode 22b) in which the electrode 22b of the rear surface 21b is bonded to the first conductive plate 11a.

While FIG. 7 only illustrates the two first semiconductor chips 20B, the four second semiconductor chips 20B each have a structure in which the electrode 22b toward the rear surface 21b is electrically and mechanically connected and bonded to the third conductive plate 11c via conductive bonding material (solder material, for example). The semiconductor device 1 according to the first embodiment thus includes the second semiconductor chips 20B each having the main surface 21a and the rear surface 21b provided with the respective electrodes (the main surface 21a provided with the electrodes 22a and 22c and the rear surface 21b provided with the electrode 22b) in which the electrode 22b of the rear surface 21b is bonded to the third conductive plate 11c.

### Wired Substrate

As illustrated in FIGS. 4-7, the wired substrate 30 includes an insulating plate 32, a first wiring part 31a (refer to FIGS. 4 and 5) and a second wiring part 31b (refer to FIGS. 6 and 7) provided on a first wiring layer on one surface side of the insulating plate 32 toward the insulated circuit substrate 10, and a third wiring part 33d (refer to FIGS. 4 and 5) and a fourth wiring part 33e (refer to FIGS. 6 and 7) provided on a second wiring layer on the other side opposite to the one surface side of the insulating plate 32. The wired substrate 30 also includes the fourth conductive pad 41d (refer to FIG. 4) and the fifth conductive pad 41e (refer to FIG. 6) provided on the second wiring layer on the other side opposite to the one surface side of the insulating plate 32. The first, second, third, and fourth wiring parts 31a, 31b, 33d, and 33e are stacked on the insulating plate 32.

The wired substrate 30 has a rectangular, particularly oblong shape in the planar view, for example. The wired substrate 30 has two short sides opposed to each other in the X direction (the longitudinal direction) and extending in the Y direction (the short-side direction) perpendicular to the X direction, and two long sides opposed to each other in the Y direction and extending in the X direction. The wired substrate 30 has a thickness in the Z direction perpendicular to the X direction and the Y direction. The first embodiment illustrates the case in which two short sides 32a and 32b of the insulating plate 32 correspond to the two short sides of the wired substrate 30, and two long sides 32c and 32d of the insulating plate 32 correspond to the two long sides of the wired substrate 30.

The wired substrate 30 is a typical printed wired substrate, and, although not limited to this case, has a two-layer wired structure including the first wiring layer on one surface side of the insulating plate 32 and the second wiring layer on the other side opposite to the one surface side of the insulating plate 32. The first and second wiring layers are each made of copper foil. The insulating plate 32 includes an insulating resin substrate in which glass fiber is impregnated with polyimide polymer.

### Insulating Plate

As illustrated in FIG. 3A, the insulating plate 32 has an oblong shape provided with recesses in the planar view. In particular, the insulating plate 32 has the two short sides 32a and 32b opposed to each other in the X direction and extending in the Y direction, and the two long sides 32c and 32d opposed to each other in the Y direction and extending in the X direction. The insulating plate 32 also has recesses 34a and 34b each recessed from the one short side 32a which is one of the two short sides 32a and 32b toward the other short side 32b with a predetermined width, and a recess 34c recessed from the other short side 32b toward the one short side 32a with a predetermined width.

The recess 34a is provided at a position corresponding to the first conductive pad 41a so that the first conductive pad 41a is not superposed on the insulating plate 32 in the planar view, namely, the first conductive pad 41a is located on the inside of the recess 34a. The recess 34b is provided at a position corresponding to the second conductive pad 41b so that the second conductive pad 41b is not superposed on the insulating plate 32 in the planar view, namely, the second conductive pad 41b is located on the inside of the recess 34b. The recess 34c is provided at a position corresponding to the third conductive pad 41c so that the third conductive pad 41c is not superposed on the insulating plate 32 in the planar view, namely, the third conductive pad 41c is located on the inside of the recess 34c.

### First and Second Wiring Parts

As illustrated in FIGS. 4 and 5, the first wiring part 31a is electrically connected to the electrodes 22a of the first semiconductor chips 20A through the conductive pins 37a. While FIGS. 4 and 5 illustrate only the two first semiconductor chips 20A, the first wiring part 31a is electrically connected to each of the electrodes 22a of the four first semiconductor chips 20A through the respective conductive pins 37a.

As illustrated in FIGS. 6 and 7, the second wiring part 31b is electrically connected to the electrodes 22a of the second semiconductor chips 20B through the conductive pins 37b. While FIGS. 6 and 7 illustrate only the two second semiconductor chips 20B, the second wiring part 31b is electrically connected to each of the electrodes 22a of the four second semiconductor chips 20B through the respective conductive pins 37b.

Namely, the semiconductor device 1 according to the first embodiment includes the wired substrate 30 arranged over the one surface of the insulated circuit substrate 10 separately from the first and second semiconductor chips 20A and 20B, and including the first wiring part 31a electrically connected to the respective electrodes 22a toward the main surface 21a of the first semiconductor chips 20A and the second wiring part 31b electrically connected to the respective electrodes 22a toward the main surface 21a of the second semiconductor chips 20B.

### Third and Fourth Wiring Parts

As illustrated in FIGS. 4 and 5, the third wiring part 33d is electrically connected to the electrodes 22c of the first semiconductor chips 20A through the conductive pins 37d. The third wiring part 33d is also electrically connected to each of the electrodes 22c of the four first semiconductor chips 20A through the respective conductive pins 37d.

As illustrated in FIGS. 6 and 7, the fourth wiring part 33e is electrically connected to the electrodes 22c of the second semiconductor chips 20B through the conductive pins 37e. The fourth wiring part 33e is also electrically connected to each of the electrodes 22c of the four second semiconductor chips 20B through the respective conductive pins 37e.

### Conductive Pins

As illustrated in FIG. 5, one ends of the conductive pins 37a are press-fitted to the wired substrate 30 so as to be electrically and mechanically joined to the first wiring part 31a of the wired substrate 30. The other ends of the conductive pins 37a are downwardly in contact with the electrodes 22a of the semiconductor chips 20A so as to be electrically and mechanically joined to each other via bonding material (not illustrated). The bonding material to be used can be solder material, for example. The conductive pins 37a are isolated from each of the second wiring part 31b, the third wiring part 33d, and the fourth wiring part 33e of the wired substrate 30.

As illustrated in FIG. 5, one ends of the conductive pins 37d are press-fitted to the wired substrate 30 so as to be electrically and mechanically joined to the third wiring part 31d of the wired substrate 30. The other ends of the conductive pins 37d are downwardly in contact with the electrodes 22c of the semiconductor chips 20A so as to be electrically and mechanically joined to each other via bonding material (not illustrated). The bonding material to be used can be solder material, for example. The conductive pins 37d are isolated from each of the first wiring part 31a, the second wiring part 31b, and the fourth wiring part 33e of the wired substrate 30.

As illustrated in FIG. 7, one ends of the conductive pins 37b are press-fitted to the wired substrate 30 so as to be electrically and mechanically joined to the second wiring part 31b of the wired substrate 30. The other ends of the conductive pins 37b are downwardly in contact with the electrodes 22a of the semiconductor chips 20B so as to be electrically and mechanically joined to each other via bonding material (not illustrated). The bonding material to be used can be solder material, for example. The conductive pins 37b are isolated from each of the first wiring part 31a, the third wiring part 33d, and the fourth wiring part 33e of the wired substrate 30.

As illustrated in FIG. 7, one ends of the conductive pins 37e are press-fitted to the wired substrate 30 so as to be electrically and mechanically joined to the fourth wiring part 31e of the wired substrate 30. The other ends of the conductive pins 37e are downwardly in contact with the electrodes 22c of the semiconductor chips 20B so as to be electrically and mechanically joined to each other via bonding material (not illustrated). The bonding material to be used can be solder material, for example. The conductive pins 37e are isolated from each of the first wiring part 31a, the second wiring part 31b, and the third wiring part 33d of the wired substrate 30.

The conductive pins 37a, 37b, 37d, and 37e each have a columnar shape, for example.

### First and Second Conductive Members

As illustrated in FIGS. 4 and 5, the first conductive members 35 extend in the Z direction. One ends of the first conductive members 35 are press-fitted to the wired substrate 30 so as to be electrically and mechanically joined to the first wiring part 31a of the wired substrate 30. The other ends of the first conductive members 35 are downwardly in contact with the third conductive plate 11c of the insulated circuit substrate 10 so as to be electrically and mechanically joined to each other via bonding material (not illustrated). The bonding material to be used can be solder material, for example.

The semiconductor device 1 according to the first embodiment thus includes the first conductive members 35 connected to each of the first wiring part 31a of the wired substrate 30 and the third conductive plate 11c of the insulated circuit substrate 10.

As illustrated in FIGS. 6 and 7, the second conductive members 36 extend in the Z direction. One ends of the second conductive members 36 are press-fitted to the wired substrate 30 so as to be electrically and mechanically joined to the second wiring part 31b of the wired substrate 30. The other ends of the second conductive members 36 are downwardly in contact with the second conductive plate 11b of the insulated circuit substrate 10 so as to be electrically and mechanically joined to each other via bonding material (not illustrated). The bonding material to be used can be solder material, for example.

The semiconductor device 1 according to the first embodiment thus includes the second conductive members 36 connected to each of the second wiring part 31b of the wired substrate 30 and the second conductive plate 11b of the insulated circuit substrate 10.

The first and second conductive members 35 and 36 are each a conductive pin having a columnar shape, for example.

### Conductive Pads

### First to Third Conductive Pads

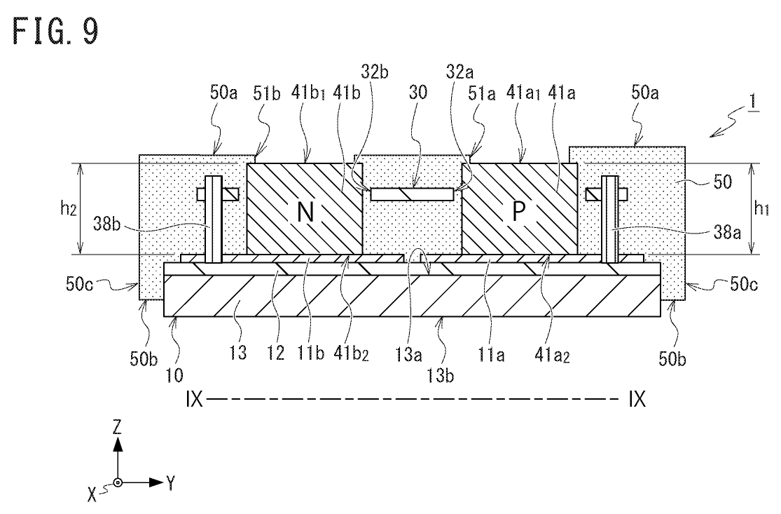

As illustrated in FIGS. 4 and 9, the first conductive pad 41a is arranged on the first conductive plate 11a on one surface side of the insulated circuit substrate 10 so as to be electrically and mechanically connected to the first conductive plate 11a via bonding material (not illustrated). The first conductive pad 41a has a top surface 41a₁ and a bottom surface 41a₂ opposed to each other in the Z direction. The bottom surface 41a₂ is located toward the first conductive plate 11a so as to be electrically and mechanically connected to each other, and the top surface 41a₁ is evenly flat.

As illustrated in FIGS. 6 and 9, the second conductive pad 41b is arranged on the second conductive plate 11b on one surface side of the insulated circuit substrate 10 so as to be electrically and mechanically connected to the second conductive plate 11b via bonding material (not illustrated). The second conductive pad 41b has a top surface 41b₁and a bottom surface 41b₂ opposed to each other in the Z direction. The bottom surface 41b₂ is located toward the second conductive plate 11b so as to be electrically and mechanically connected to each other, and the top surface 41b₁ is evenly flat.

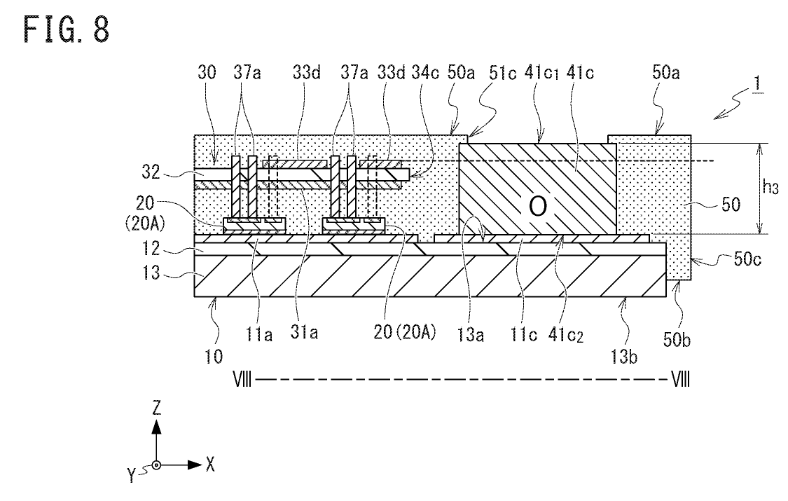

As illustrated in FIG. 8, the third conductive pad 41c is arranged on the third conductive plate 11c on one surface side of the insulated circuit substrate 10 so as to be electrically and mechanically connected to the third conductive plate 11c via bonding material (not illustrated). The third conductive pad 41c has a top surface 41c₁ and a bottom surface 41c₂ opposed to each other in the Z direction. The bottom surface 41c₂ is located toward the third conductive plate 11c so as to be electrically and mechanically connected to each other, and the top surface 41c₁ is evenly flat.

As described above, the semiconductor device 1 according to the first embodiment includes:
the first conductive pad 41a arranged on the first conductive plate 11a on one surface side of the insulated circuit substrate 10 so as to be connected to the first conductive plate 11a, and having the flat top surface 41a₁;
the second conductive pad 41b arranged on the second conductive plate 11b on one surface side of the insulated circuit substrate 10 so as to be connected to the second conductive plate 11b, and having the flat top surface 41b₁; and
the third conductive pad 41c arranged on the third conductive plate 11c on one surface side of the insulated circuit substrate 10 so as to be connected to the third conductive plate 11c, and having the flat top surface 41c₁.

The first conductive pad 41a, the second conductive pad 41b, and the third conductive pad 41c each serve as an external terminal.

### Fourth and Fifth Conductive Pads

As illustrated in FIG. 4, the fourth conductive pad 41d is arranged on the insulating plate 32 of the wired substrate 30 on the surface side opposite to the surface toward the insulated circuit substrate 10. The fourth conductive pad 41d is, although not illustrated in detail, integrated with the third wiring part 33d of the wired substrate 30 so as to be electrically and mechanically connected to each other. The fourth conductive pad 41d has a top surface 41d₁ and a bottom surface 41d₂ opposed to each other in the Z direction. The bottom surface 41d₂ is located toward the insulating plate 32 so as to be connected to each other, and the top surface 41d₁ is evenly flat.

As illustrated in FIG. 6, the fifth conductive pad 41e is also arranged on the insulating plate 32 of the wired substrate 30 on the surface side opposite to the surface toward the insulated circuit substrate 10, as in the case of the fourth conductive pad 41d. The fifth conductive pad 41e is integrated with the fourth wiring part 33e of the wired substrate 30 so as to be electrically and mechanically connected to each other. The fifth conductive pad 41e has a top surface 41e₁ and a bottom surface 41e₂opposed to each other in the Z direction. The bottom surface 41e₂ is located toward the insulating plate 32 so as to be connected to each other, and the top surface 41e₁ is evenly flat.

As described above, the semiconductor device 1 according to the first embodiment includes the fourth conductive pad 41d and the fifth conductive pad 41e arranged on the wired substrate 30 and having the flat top surfaces 41d₁ and 41e₁.

### Connection Path

As illustrated in FIGS. 4 and 5, the first conductive pad 41a is electrically connected to the electrodes 22b (the drain electrodes) of the first semiconductor chips 20A through the first conductive plate 11a. The electrodes 22a (the source electrodes) of the first semiconductor chips 20A are electrically connected to the third conductive plate 11c through the conductive pins 37a, the first wiring part 31a of the wired substrate 30, and the first conductive members 35. As illustrated in FIG. 8, the third conductive plate 11c is electrically connected to the third conductive pad 41c. The semiconductor device 1 according to the first embodiment thus has a configuration in which the first conductive pad 41a and the third conductive pad 41c are electrically connected to each other through the first conductive plate 11a, the first semiconductor chips 20A, the first wiring part 31a of the wired substrate 30, the first conductive members 35, and the third conductive plate 11c when the transistors mounted on the first semiconductor chips 20A start operating to be in an ON-state.

As illustrated in FIGS. 6 and 7, the second conductive pad 41b is electrically connected to the electrodes 22a (the source electrodes) of the second semiconductor chips 20B through the second conductive plate 11b, the second conductive members 36, the second wiring part 31b of the wired substrate 30, and the conductive pins 37b. The electrodes 22b (the drain electrodes) of the second semiconductor chips 20B are electrically connected to the third conductive plate 11c. As illustrated in FIG. 8, the third conductive plate 11c is electrically connected to the third conductive pad 41c. The semiconductor device 1 according to the first embodiment thus has a configuration in which the second conductive pad 41b and the third conductive pad 41c are electrically connected to each other through the second conductive plate 11b, the second conductive members 36, the second wiring part 31b of the wired substrate 30, the conductive pins 37b, the second semiconductor chips 20B, and the third conductive plate 11c when the transistors mounted on the second semiconductor chips 20B start operating to be in an ON-state.

As described above, the fourth conductive pad 41d illustrated in FIGS. 4 and 5 is electrically connected to the third wiring part 33d of the wired substrate 30. The third wiring part 33d is electrically connected to the electrodes 22c (the gate electrodes) of the first semiconductor chips 20A through the conductive pins 37d. Namely, the fourth conductive pad 41d is electrically connected to the electrodes 22c (the gate electrodes) of the first semiconductor chips 20A through the third wiring part 33d of the wired substrate 30 and the conductive pins 37d.

As described above, the fifth conductive pad 41e illustrated in FIGS. 6 and 7 is electrically connected to the fourth wiring part 33e of the wired substrate 30. The fourth wiring part 33e is electrically connected to the electrodes 22c (the gate electrodes) of the second semiconductor chips 20B through the conductive pins 37e. Namely, the fifth conductive pad 41e is electrically connected to the electrodes 22c (the gate electrodes) of the second semiconductor chips 20B through the fourth wiring part 33e of the wired substrate 30 and the conductive pins 37e.

### Arrangement of Conductive Pads

As illustrated in FIG. 3A, the first conductive pad 41a and the second conductive pad 41b each have a rectangular, particularly oblong shape in the planar view, for example. The first conductive pad 41a and the second conductive pad 41b are both arranged toward the short side 12a of the insulating plate 12 in the planar view. The first conductive pad 41a is located closer to the long side 12c of the insulating plate 12 than the second conductive pad 41b in the planar view, and the second conductive pad 41b is located closer to the long side 12d of the insulating plate 12 than the first conductive pad 41a in the planar view. The first conductive pad 41a and the second conductive pad 41b are separately arranged in the Y direction with a predetermined gap provided.

As illustrated in FIG. 3A, the fourth conductive pad 41d, the third conductive pad 41c, and the fifth conductive pad 41e each have a rectangular, particularly oblong shape in the planar view, for example. The fourth conductive pad 41d, the third conductive pad 41c, and the fifth conductive pad 41e are each arranged toward the short side 12b of the insulating plate 12 in the planar view. The fourth conductive pad 41d, the third conductive pad 41c, and the fifth conductive pad 41e are arranged in this order separately from each other in the Y direction with a predetermined gap provided. The third conductive pad 41c is located toward the short side 12b of the insulating plate substantially in the middle of the short side 12b. The fourth conductive pad 41d is located closer to the long side 12c of the insulating plate 12 than the third conductive pad 41c in the planar view. The fifth conductive pad 41e is located closer to the long side 12d of the insulating plate 12 than the third conductive plate 41c in the planar view.

### Resin Sealing Body

As illustrated in FIG. 2, the resin sealing body 50 has a rectangular, particularly oblong shape in the planar view, for example. The resin sealing body 50 has a top surface 50a as a first surface and a bottom surface 50b as a second surface opposed to each other in the thickness direction (the Z direction), as illustrated in FIG. 4. The resin sealing body 50 seals the insulated circuit substrate 10, the first and second semiconductor chips 20A and 20B, and the wired substrate 30, and also seals the first and second conductive members 35 and 36, the conductive pins 37a, 37b, 37d, and 37e, the positioning pins 38a to 38d, and the like in a state in which the respective top surfaces 41a₁, 41b₁, 41c₁, 41d₁, and 41e₁of the first, second, third, fourth, and fifth conductive pads 41a, 41b, 41c, 41d, and 41e are exposed outward through the top surface 50a, and the cooling plate 13 is exposed outward through the bottom surface 50b, as illustrated in FIGS. 2 and 4-9.

As described above, the semiconductor device 1 according to the first embodiment includes the resin sealing body 50 having the top surface 50a and the bottom surface 50b opposed to each other in the Z direction to seal the insulated circuit substrate 10, the first and second semiconductor chips 20A and 20B, the wired substrate 30, and the like in the state in which the respective top surfaces 41a₁, 41b₁, 41c₁, 41d₁, and 41e₁ of the first, second, third, fourth, and fifth conductive pads 41a, 41b, 41c, 41d, and 41e are exposed outward through the top surface 50a, and the cooling plate 13 is exposed outward through the bottom surface 50b.

The top surface 50a and the bottom surface 50b of the resin sealing body 50 described in the first embodiment correspond to specific examples of "a first surface" and "a second surface" according to the present technology.

The resin sealing body 50 includes thermosetting epoxy resin, for example, and is formed by transfer molding suitable for mass production. The transfer molding method can form the resin sealing body 50 at lower costs than a potting method for forming such a resin sealing body by use of thermoplastic polymer in a gel state.

### Vertical Structure of Conductive Pads

As illustrated in FIGS. 4-9, the respective top surfaces 41a₁, 41b₁, and 41c₁ of the first conductive pad 41a, the second conductive pad 41b, and the third conductive pad 41c are positioned closer to the top surface 50a of the resin sealing body 50 than the wired substrate 30 in the vertical cross-sectional view. Namely, the respective top surfaces 41a₁, 41b₁, and 41c₁ of the first conductive pad 41a, the second conductive pad 41b, and the third conductive pad 41c are located between the top surface 50a of the resin sealing body 50 and the wired substrate 30 in the vertical cross-sectional view.

As illustrated in FIGS. 4-7, the respective top surfaces 41d₁ and 41e₁ of the fourth conductive pad 41d and the fifth conductive pad 41e are also positioned closer to the top surface 50a of the resin sealing body 50 than the wired substrate 30 in the vertical cross-sectional view, as in the case of the respective top surfaces 41a₁, 41b₁, and 41c₁ of the first conductive pad 41a, the second conductive pad 41b, and the third conductive pad 41c. The respective top surfaces 41d₁ and 41e₁ of the fourth conductive pad 41d and the fifth conductive pad 41e are also located between the top surface 50a of the resin sealing body 50 and the wired substrate 30 in the vertical cross-sectional view, as in the case of the respective top surfaces 41a₁, 41b₁, and 41c₁ of the first conductive pad 41a, the second conductive pad 41b, and the third conductive pad 41c.

As illustrated in FIGS. 4-9, the first conductive pad 41a, the second conductive pad 41b, and the third conductive pad 41c each have a greater thickness in the Z direction than the wired substrate 30.

As illustrated in FIGS. 3A, 4, and 9, the first conductive pad 41a passes through the inside of the recess 34a of the wired substrate 30 to extend across the one surface and the opposite surface of the wired substrate 30 in the Z direction. The first conductive pad 41a is directly fixed to the insulated circuit substrate 10.

As illustrated in FIGS. 3A, 6, and 9, the second conductive pad 41b similarly passes through the inside of the recess 34b of the wired substrate 30 to extend across the one surface and the opposite surface of the wired substrate 30 from in the Z direction. The second conductive pad 41b is also directly fixed to the insulated circuit substrate 10.

As illustrated in FIGS. 3A and 8, the third conductive pad 41c similarly passes through the inside of the recess 34c of the wired substrate 30 to extend across the one surface and the opposite surface of the wired substrate 30 in the Z direction. The third conductive pad 41c is also directly fixed to the insulated circuit substrate 10.

### Exposure of Conductive Pads

As illustrated in FIGS. 2, 4, and 9, a middle region of the top surface 41a₁ of the first conductive pad 41a is exposed to a first bonding opening (a main terminal opening) 51a provided on the top surface 50a side of the resin sealing body 50, and an outer edge region surrounding the middle region of the top surface 41a₁ is covered continuously along the outer circumference with the resin sealing body 50. The first bonding opening 51a has a planar shape similar to that of the first conductive pad 41a in the planar view, and has a smaller planar size than the first conductive pad 41a. The first conductive pad 41a thus has the middle region of the top surface 41a₁ exposed to the outside of the resin sealing body 50, and has the outer edge region of the top surface 41a₁covered with the resin sealing body 50.

As illustrated in FIGS. 2, 6, and 9, a middle region of the top surface 41b₁ of the second conductive pad 41b is similarly exposed to a second bonding opening (a main terminal opening) 51b provided on the top surface 50a side of the resin sealing body 50, and an outer edge region surrounding the middle region of the top surface 41b₁ is covered continuously along the outer circumference with the resin sealing body 50. The second bonding opening 51b has a planar shape similar to that of the second conductive pad 41b in the planar view, and has a smaller planar size than the second conductive pad 41b. The second conductive pad 41b thus has the middle region of the top surface 41b₁ exposed to the outside of the resin sealing body 50, and has the outer edge region of the top surface 41b₁ covered with the resin sealing body 50, as in the case of the first conductive pad 41a.

As illustrated in FIGS. 2 and 8, a middle region of the top surface 41c₁ of the third conductive pad 41c is similarly exposed to a third bonding opening (a main terminal opening) 51c provided on the top surface 50a side of the resin sealing body 50, and an outer edge region surrounding the middle region of the top surface 41c₁ is covered continuously along the outer circumference with the resin sealing body 50. The third bonding opening 51c has a planar shape similar to that of the third conductive pad 41c in the planar view, and has a smaller planar size than the third conductive pad 41c. The third conductive pad 41c thus has the middle region of the top surface 41c₁ exposed to the outside of the resin sealing body 50, and has the outer edge region of the top surface 41c₁ covered with the resin sealing body 50, as in the case of the first conductive pad 41a.

As illustrated in FIGS. 2 and 4, a middle region of the top surface 41d₁ of the fourth conductive pad 41d is similarly exposed to a fourth bonding opening (a main terminal opening) 51d provided on the top surface 50a side of the resin sealing body 50, and an outer edge region surrounding the middle region of the top surface 41d₁ is covered continuously along the outer circumference with the resin sealing body 50. The fourth bonding opening 51d has a planar shape similar to that of the fourth conductive pad 41d in the planar view, and has a smaller planar size than the fourth conductive pad 41d. The fourth conductive pad 41d thus has the middle region of the top surface 41d₁ exposed to the outside of the resin sealing body 50, and has the outer edge region of the top surface 41d₁ covered with the resin sealing body 50, as in the case of the first conductive pad 41a.

As illustrated in FIGS. 2 and 6, a middle region of the top surface 41e₁ of the fifth conductive pad 41e is similarly exposed to a fifth bonding opening (a main terminal opening) 51e provided on the top surface 50a side of the resin sealing body 50, and an outer edge region surrounding the middle region of the top surface 41e₁ is covered continuously along the outer circumference with the resin sealing body 50. The fifth bonding opening 51e has a planar shape similar to that of the fifth conductive pad 41e in the planar view, and has a smaller planar size than the fifth conductive pad 41e. The fifth conductive pad 41e thus has the middle region of the top surface 41e₁ exposed to the outside of the resin sealing body 50, and has the outer edge region of the top surface 41e₁ covered with the resin sealing body 50, as in the case of the first conductive pad 41a.

### Heights of Conductive Pads

Although not limited to this case, the respective top surfaces 41a₁, 41b₁, and 41c₁ of the first conductive pad 41a, the second conductive pad 41b, and the third conductive pad 41c have common heights h₁, h₂, and h₃ (refer to FIGS. 5, 7, and 8), in terms of a design value, from the insulated circuit substrate 10, for example. Namely, the respective top surfaces 41a₁, 41b₁, and 41c₁ of the first conductive pad 41a, the second conductive pad 41b, and the third conductive pad 41c are located on a plane level with each other.

Although not limited to this case, the respective top surfaces 41d₁and 41e₁of the fourth conductive pad 41d and the fifth conductive pad 41e have also common heights h₄ and h₅ (refer to FIGS. 5 and 7), in terms of a design value, from the insulated circuit substrate 10, for example.

### Vertical Structure of Cooling Plate

As illustrated in FIG. 4, the cooling plate 13 has a top surface 13a and a bottom surface 13b opposed to each other in the Z direction which is the thickness direction. The top surface 13a is fixed to the insulating plate 12, and the bottom surface 13b is exposed outward through the bottom surface 50b of the resin sealing body 50. The bottom surface 13b of the cooling plate 13 protrudes downward from the bottom surface 50b of the resin sealing body 50. The cooling plate 13 is thus arranged on both the inside and the outside of the bottom surface 50b of the resin sealing body 50 so as to protrude to the outside from the bottom surface 50b of the resin sealing body 50.

### Positioning Pins

As illustrated in FIG. 3A, the positioning pin 38a is located adjacent to the corner at which the one short side 32a and the one long side 32c of the wired substrate 30 intersect with each other in the planar view. The positioning pin 38b is located adjacent to the corner at which the one short side 32a and the other long side 32d of the wired substrate 30 intersect with each other in the planar view. The positioning pin 38c is located adjacent to the corner at which the other short side 32b and the one long side 32c of the wired substrate 30 intersect with each other in the planar view. The positioning pin 38d is located adjacent to the corner at which the other short side 32b and the other long side 32d of the wired substrate 30 intersect with each other in the planar view. As illustrated in FIG. 3C, the positioning pins 38a to 38d are arranged separately from each other at the four corners on two diagonals Ld₁ and Ld₂ of the wired substrate 30 in the planar view.

As illustrated in FIG. 9, the respective positioning pins 38a and 38b extend in the thickness direction (the Z direction) of each of the wired substrate 30 and the insulated circuit substrate 10, and have one end press-fitted to the wired substrate 30 and the other end opposite to the one end press-fitted to the insulated circuit substrate 10. Although not illustrated in detail, the respective positioning pins 38c and 38d also extend in the thickness direction (the Z direction) of each of the wired substrate 30 and the insulated circuit substrate 10, and have one end press-fitted to the wired substrate 30 and the other end opposite to the one end press-fitted to the insulated circuit substrate 10, as in the case of the positioning pins 38a and 38b.

### Support of Wired Substrate

As illustrated in FIGS. 4 and 5, the wired substrate 30 is supported on the insulated circuit substrate 10 via the first semiconductor chips 20A and the conductive pins 37a and 37d arranged next to each other and extending in the vertical direction (the Z direction). As illustrated in FIGS. 6 and 7, the wired substrate 30 is also supported on the insulated circuit substrate 10 via the second semiconductor chips 20B and the conductive pins 37b and 37e arranged next to each other and extending in the vertical direction (the Z direction). As illustrated in FIGS. 4-7, the wired substrate 30 is also supported on the insulated circuit substrate 10 via each of the first conductive members 35 and the second conductive members 36. The wired substrate 30 is also supported on the insulated circuit substrate 10 via each of the four positioning pins 38a to 3d8.

### Material

The first and second conductive members 35 and 36, the conductive pins 37a, 37b, 37d, and 37e, the positioning pins 38a to 38d, and the first to fifth conductive pads 41a to 41e each include conductive material such as copper (Cu), a Cu alloy, aluminum (Al), and an Al alloy, for example.

### METHOD OF MANUFACTURING SEMICONDUCTOR DEVICE

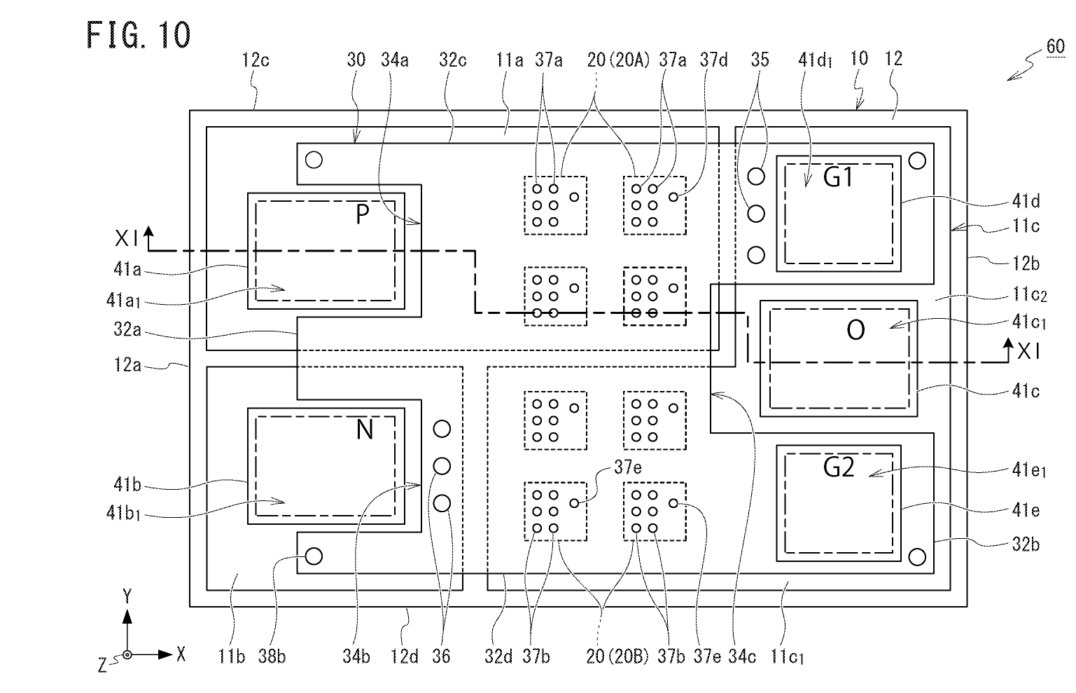

A method of manufacturing the semiconductor device 1 according to the first embodiment is described below with reference to FIGS. 10-14.

The explanations of the manufacturing method according to first embodiment are made below while focusing mainly on a process for forming the resin sealing body 50 included in the method of manufacturing the semiconductor device 1. The resin sealing body 50 is formed by transfer molding suitable for mass production.

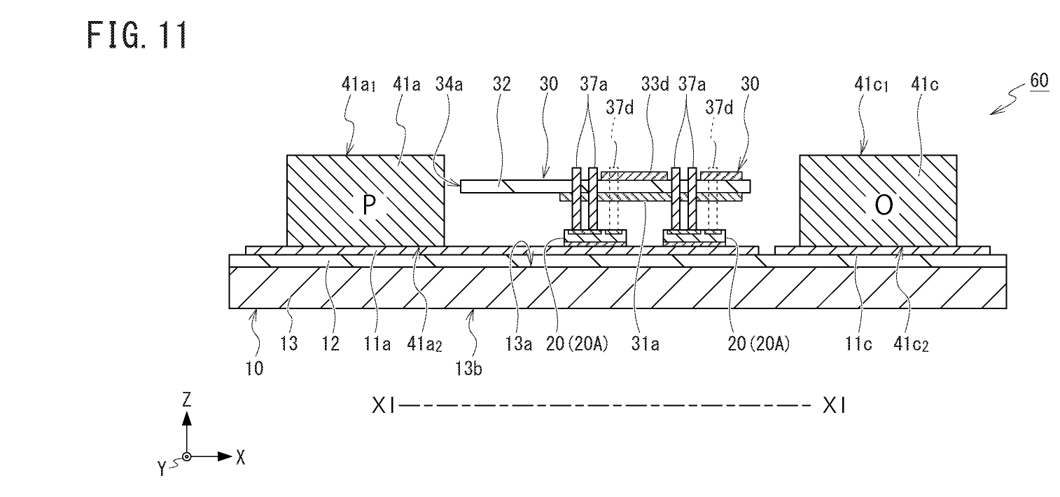

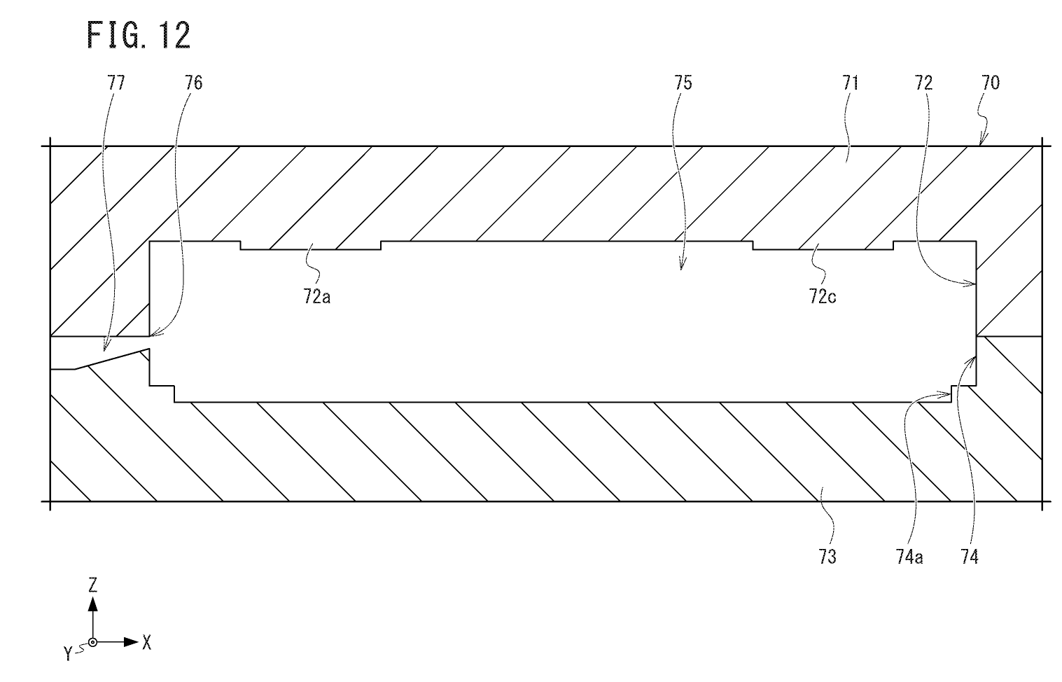

First, an assembly structure body (an assembly component) 60 illustrated in FIGS. 10 and 11 is prepared, and a molding metal die 70 illustrated in FIG. 12 is prepared.

The assembly structure body 60 has basically substantially the same structure as the semiconductor device 1 as illustrated in FIGS. 1 - 9 except for the resin sealing body 50.

In particular, as illustrated in FIGS. 10 and 11, the assembly structure body 60 includes the insulated circuit substrate 10 including the first to third conductive plates 11a, 11b, and 11c on one surface side and the cooling plate 13 on the opposite side of the one surface side, the first semiconductor chips 20A and the second semiconductor chips 20B mounted on the one surface side of the insulated circuit substrate 10, and the wired substrate 30 arranged on the one surface side of the insulated circuit substrate 10 separately from the respective first and second semiconductor chips 20A and 20B.

The assembly structure body 60 further includes the first to third conductive pads 41a, 41b, and 41c fixed to the one surface side of the insulated circuit substrate 10, and the fourth and fifth conductive pads 41d and 41e provided on the wired substrate 30.

The assembly structure body 60 further includes the first and second conductive members 35 and 36, the conductive pins 37a, 37b, 37d, and 37e, and the positioning members 38a to 38d.

The insulated circuit substrate 10 and the wired substrate 30 each having a thickness in the Z direction are stacked with a predetermined gap provided in the Z direction. The wired substrate 30 is supported on the insulated circuit substrate 10 separately from the insulated circuit substrate 10 and the semiconductor chips 20 (20A and 20B) by the first and second conductive members 35 and 36, the conductive pins 37a, 37b, 37d, and 37e, the positioning members 38a to 38d, and the like.

The other specific structures conform to those as illustrated in FIGS. 1 - 9 except for the resin sealing body 50.

As illustrated in FIG. 12, the molding metal die 70 has a cavity 75 defined by an upper die 71, a lower die 73, a recess 72 provided at a joint surface part of the upper die 71, and a recess 74 provided at a joint surface part of the lower die 73, and a runner 77 integrally connected to the cavity 75 via an injection gate 76. A pot (not illustrated) for introducing polymer tablets is also connected to the runner 77.

As illustrated in FIG. 12, the molding metal die 70 also has a first projection 72a provided on the bottom of the recess 72 of the upper die 71 and having a flat top surface similar to the top surface 41a₁ of the first conductive pad 41a at a position corresponding to the first conductive pad 41a in the assembly structure body 60, and a third projection 72c provided on the bottom of the recess 72 of the upper die 71 and having a flat top surface similar to the top surface 41c₁ of the third conductive pad 41c at a position corresponding to the third conductive pad 41c in the assembly structure body 60.

The molding metal die 70 also has a recess 74a provided on the bottom of the recess 74 of the lower die 73 at a position corresponding to the cooling plate 13 in the assembly structure body 60.

Although not illustrated, the molding metal die 70 also has a second projection provided on the bottom of the recess 72 of the upper die 71 and having a flat top surface similar to the top surface 41b₁ of the second conductive pad 41b at a position corresponding to the second conductive pad 41b in the assembly structure body 60, a fourth projection provided on the bottom of the recess 72 of the upper die 71 and having a flat top surface similar to the top surface 41d₁ of the fourth conductive pad 41d at a position corresponding to the fourth conductive pad 41d in the assembly structure body 60, and a fifth projection provided on the bottom of the recess 72 of the upper die 71 and having a flat top surface similar to the top surface 41e₁ of the fifth conductive pad 41e at a position corresponding to the fifth conductive pad 41e in the assembly structure body 60.

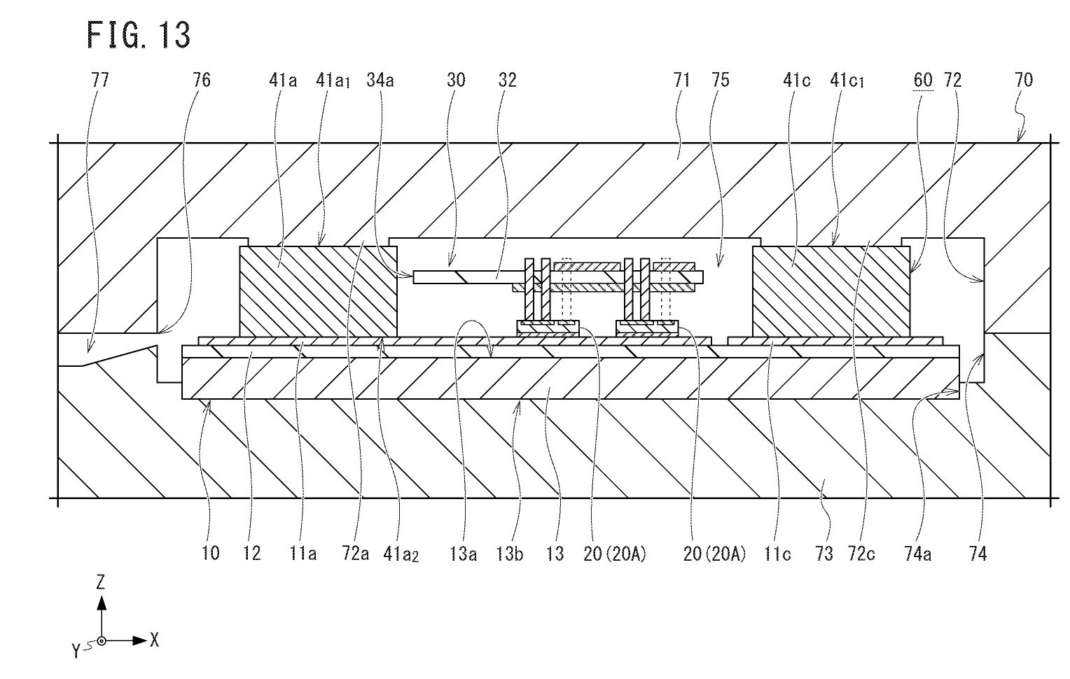

Next, as illustrated in FIG. 13, the assembly structure body 60 is placed inside the cavity 75 defined by the upper die 71 and the lower die 73 of the molding metal die 70 so as to be clamped together.

This step press-fits the bottom surface 13b of the cooling plate 13 included in the insulated circuit substrate 10 in the assembly structure body 60 and the bottom of the recess 74a of the lower die 73 (the inner wall surface of the cavity 75) together by clamping force of the molding metal die 70.

This step also press-fits the top surface 41a₁ of the first conductive pad 41a included in the assembly structure body 60 and the top surface of the first projection 72a of the upper die 71 together by the clamping force of the molding metal die 70. The direct fixation of the first conductive pad 41a to the insulated circuit substrate 10 can enhance press-fit strength, namely, tight contact between the top surface 41a₁ of the first conductive pad 41a and the top surface of the first projection 72a of the upper die 71.

This step also press-fits the top surface 41c₁ of the third conductive pad 41c included in the assembly structure body 60 and the top surface of the third projection 72c of the upper die 71 together by the clamping force of the molding metal die 70. The direct fixation of the third conductive pad 41c to the insulated circuit substrate 10 can also enhance press-fit strength, namely, tight contact between the top surface 41c₁ of the third conductive pad 41c and the top surface of the third projection 72c of the upper die 71.

Although not illustrated, this step also press-fits the top surface 41b₁ of the second conductive pad 41b included in the assembly structure body 60 and the top surface of the second projection of the upper die 71 together by the clamping force of the molding metal die 70. The direct fixation of the second conductive pad 41b to the insulated circuit substrate 10 can also enhance press-fit strength, namely, tight contact between the top surface 41b₁ of the second conductive pad 41b and the top surface of the second projection of the upper die 71.

Although not illustrated, this step also press-fits the top surface 41d₁ of the fourth conductive pad 41d included in the wired substrate 30 of the assembly structure body 60 and the top surface of the fourth projection of the upper die 71 together by the clamping force of the molding metal die 70, and press-fits the top surface 41e₁ of the fifth conductive pad 41e included in the wired substrate 30 of the assembly structure body 60 and the top surface of the fifth projection of the upper die 71 together by the clamping force of the molding metal die 70. The wired substrate 30 including the fourth and fifth conductive pads 41d and 41e is supported on the insulated circuit substrate 10 separately from the insulated circuit substrate 10 and the semiconductor chips 20 (20A and 20B) by the first and second conductive members 35 and 36, the conductive pins 37a, 37b, 37d, and 37e, the positioning members 38a to 38d, and the like, so as to enhance press-fit strength (tight contact) between the top surface 41d₁ of the fourth conductive pad 41d included in the wired substrate 30 and the top surface of the fourth projection of the upper die 71, and enhance press-fit strength (tight contact) between the top surface 41e₁ of the fifth conductive pad 41e included in the wired substrate 30 and the top surface of the fifth projection of the upper die 71.

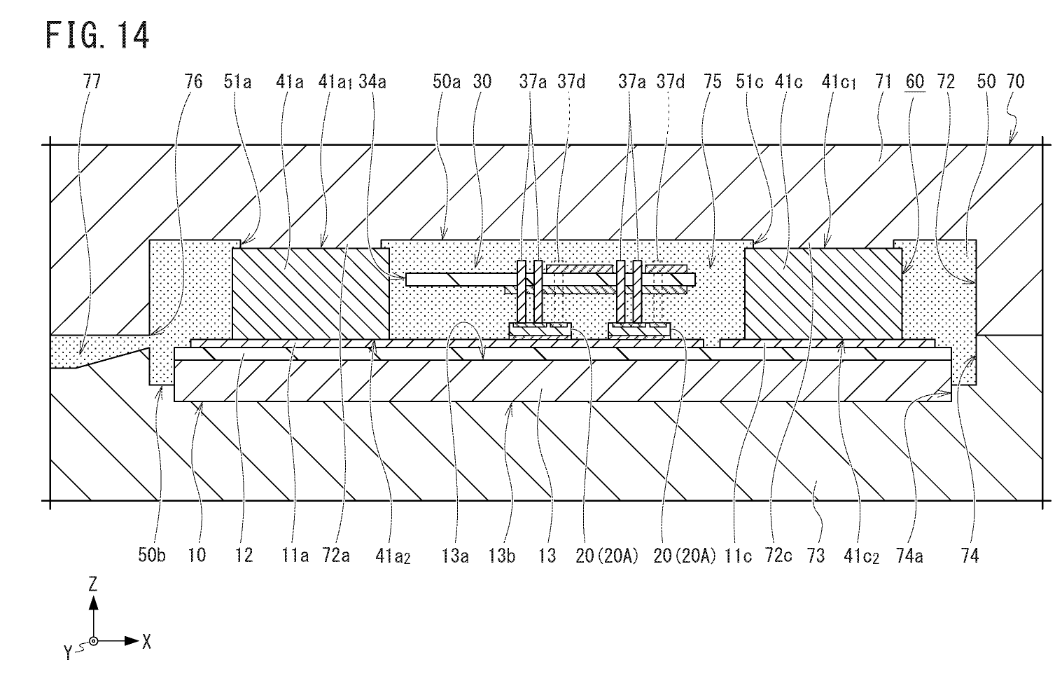

Next, thermosetting epoxy resin, for example, is injected with pressure into the cavity 75 through the runner 77 and the injection gate 76 from a pot (not illustrated) so as to form the resin sealing body 50 in the state in which the assembly structure body 60 is placed inside the cavity 75 to be clamped together, as illustrated in FIG. 14.

The above step can enhance the press-fit strength (the tight contact) between the top surface 41a₁ of the first conductive pad 41a and the top surface of the first projection 72a of the upper die 71 and the press-fit strength (the tight contact) between the top surface 41c₁ of the third conductive pad 41c and the top surface of the third projection 72c of the upper die 71, so as to avoid the entrance of the resin into the interface between the top surface 41a₁ of the first conductive pad 41a and the top surface of the first projection 72a of the upper die 71 and the entrance of the resin into the interface between the top surface 41c₁ of the third conductive pad 41c and the top surface of the third projection 72c of the upper die 71 during the resin-injection step.

Similarly, although not illustrated, the above step also can enhance the press-fit strength (the tight contact) between the top surface 41b₁ of the second conductive pad 41b and the top surface of the second projection of the upper die 71, so as to avoid the entrance of the resin into the interface between the top surface 41b₁ of the second conductive pad 41b and the top surface of the second projection of the upper die 71 during the resin-injection step.

Similarly, although not illustrated, the above step also can enhance the press-fit strength (the tight contact) between the top surface 41d₁ of the fourth conductive pad 41d and the top surface of the fourth projection of the upper die 71 and between the top surface 41e₁ of the fifth conductive pad 41e and the top surface of the fifth projection of the upper die 71, so as to avoid the entrance of the resin into the interface between the top surface 41d₁of the fourth conductive pad 41d and the top surface of the fourth projection of the upper die 71 and between the top surface 41e₁ of the fifth conductive pad 41e and the top surface of the fifth projection of the upper die 71 during the resin-injection step.

This step provides the resin sealing body 50 with a structure including the top surface 50a and the bottom surface 50b opposed to each other, in which the respective top surfaces 41a₁, 41b₁, 41c₁, 41d₁, and 41e₁ of the first, second, third, fourth, and the fifth conductive pads 41a, 41b, 41c, 41d, and 41e are exposed outward through the top surface 50a, and the bottom surface 13b of the cooling plate 13 is exposed outward through the bottom surface 50b. The resin sealing body 50 is also provided with the bonding openings 51a, 51b, 51c, 51d, and 51e to which the respective top surfaces 41a₁, 41b₁, 41c₁, 41d₁, and 41e₁ of the first to fifth conductive pads 41a, 41b, 41c, 41d, and 41e are exposed respectively.

This step seals the assembly structure body 60 with the resin sealing body 50.

Next, after the resin sealing body 50 sealing the assembly structure body 60 is removed from the molding metal die 70, extra resin pieces such as runner resin and culls adhering to the resin sealing body 50 are then removed.

The process as described above thus substantially completes the semiconductor device 1 including the assembly structure body 60 and the resin sealing body 50.

### POWER CONVERSION APPARATUS

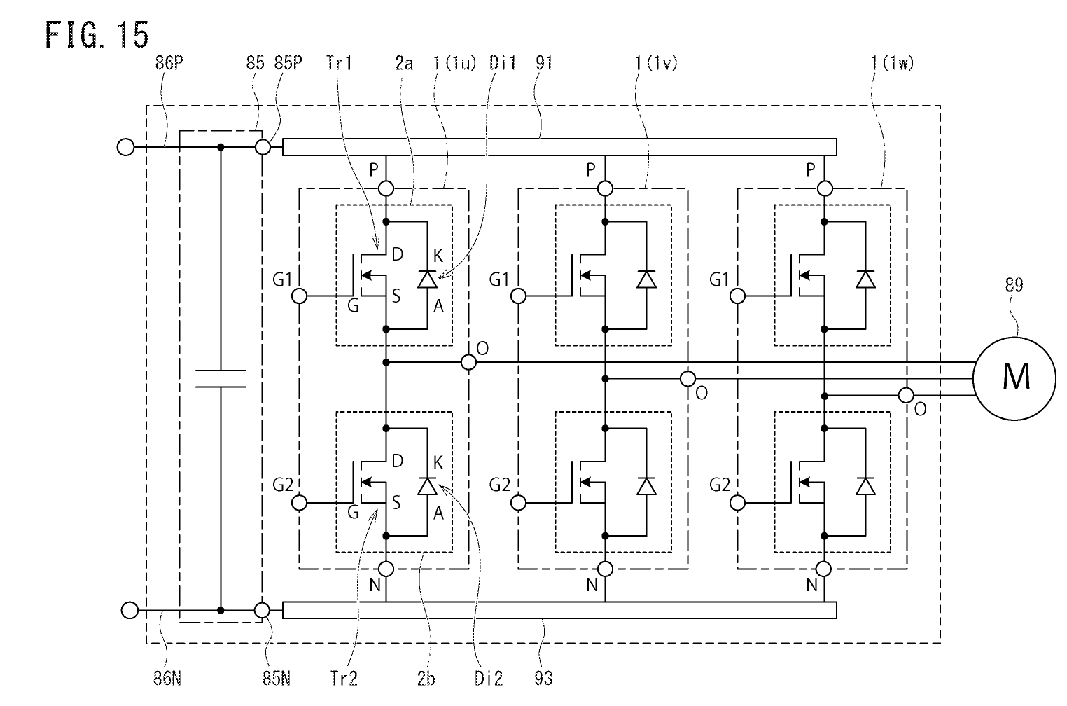

A power conversion apparatus 80 for converting electric power from DC to AC is described below as an electronic apparatus including the semiconductor device 1 as described above with reference to FIGS. 15-18.

FIG. 15 is an equivalent circuit diagram illustrating the power conversion apparatus including the three semiconductor devices as illustrated in FIG. 1.

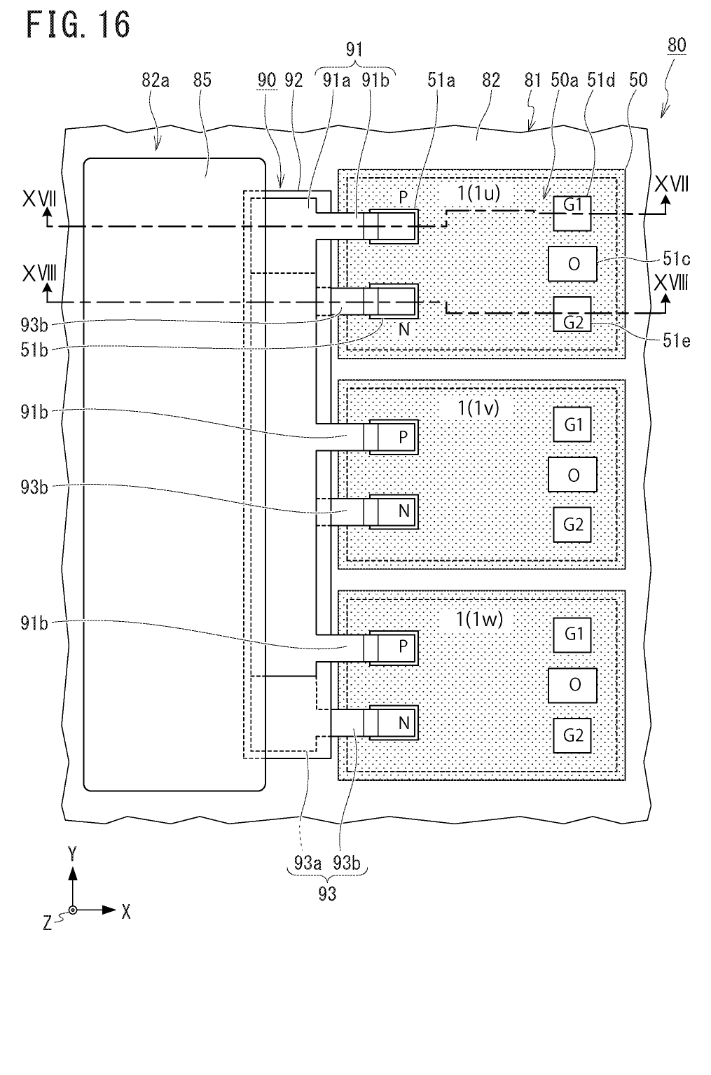

FIG. 16 is a plan view schematically illustrating a structure of the power conversion apparatus in FIG. 15.

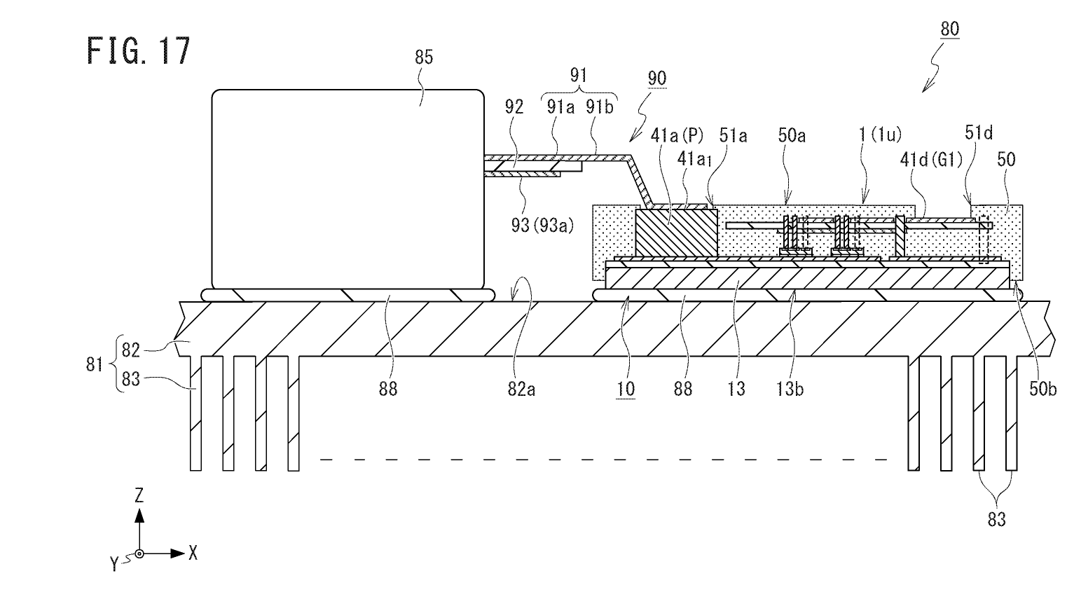

FIG. 17 is a main cross-sectional view schematically illustrating a vertical cross-sectional structure taken along line XVII-XVII in FIG. 16.

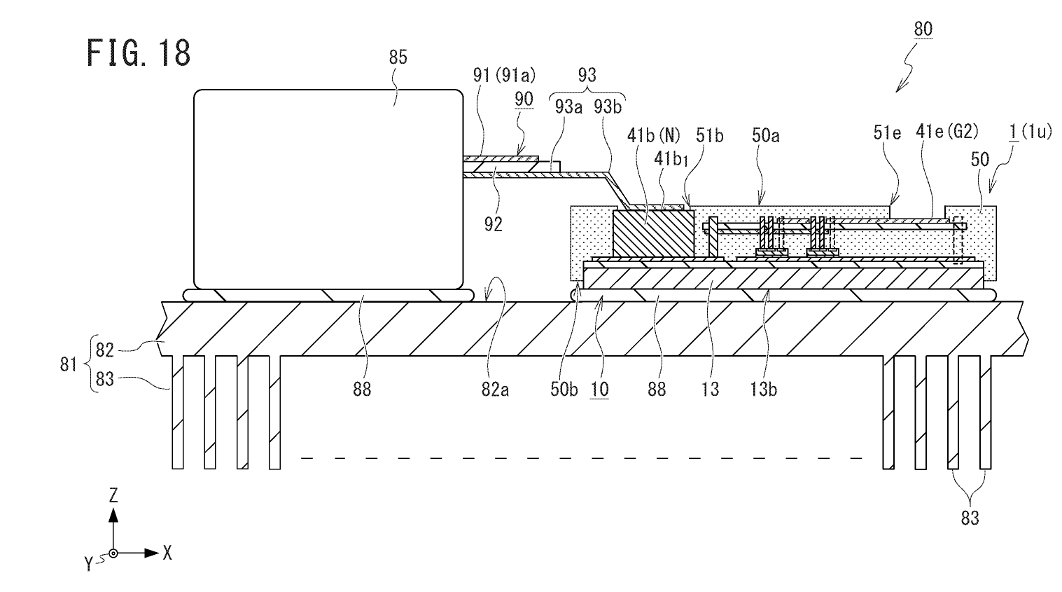

FIG. 18 is a main cross-sectional view schematically illustrating a vertical cross-sectional structure taken along line XVIII-XVIII in FIG. 16.

As illustrated in FIGS. 16, 17, and 18, the power conversion apparatus 80 includes a heat sink 81, the three semiconductor devices 1 (1u, 1v, 1w) and a capacitor unit 85 mounted on the heat sink 81, and a relay substrate 90 electrically connecting the three semiconductor devices 1 (1u, 1v, 1w) and the capacitor unit 85 together.

### Heat Sink

As illustrated in FIGS. 17 and 18, the heat sink 81 includes a base part 82 having a component-mount surface 82a, and cooling fins 83 provided on the opposite side of the component-mount surface 82a of the base part 82. The cooling fins 83 extend in the Y direction and are repeatedly arranged in the X direction at predetermined intervals, for example. The heat sink 81 includes metal such as iron and aluminum or an alloy having high heat conductivity.

### Semiconductor Devices and Capacitor Unit

As illustrated in FIG. 16, the three semiconductor devices 1 (1u, 1v, and 1w) are aligned in the Y direction, in which a longitudinal direction corresponds to the X direction. The three semiconductor devices 1 (1u, 1v, and 1w) and the capacitor unit 85 are aligned in the X direction. The three semiconductor devices 1 (1u, 1v, and 1w) are arranged so as to correspond to a U-phase, a V-phase, and a W-phase of a three-phase dielectric motor 89 illustrated in FIG. 15, for example.

As illustrated in FIGS. 17 and 18, the cooling plate 13 in the semiconductor device 1u exposed outward through the bottom surface 50b of the resin sealing body 50 is fixed to the component-mount surface 82a of the base part 82 with a heat-conductive material layer 88 interposed. Although not illustrated, the other two semiconductor devices 1v and 1w have the same structure as the semiconductor device 1u in which the cooling plate 13 exposed outward through the bottom surface 50b of the resin sealing body 50 is fixed to the component-mount surface 82a of the base part 82 with the heat-conductive material layer 88 interposed.

As illustrated in FIGS. 17 and 18, the capacitor unit 85 is also fixed to the component-mount surface 82a of the base part 82 with the heat-conductive material layer 88 interposed. The first embodiment illustrates a case of using heat-conductive grease for the heat-conductive material layer 88.

### Relay Substrate

As illustrated in FIGS. 17 and 18, the relay substrate 90 includes an insulating plate 92, a positive-electrode conductive plate 91 provided on one surface of the insulating plate 92, and a negative-electrode conductive plate 93 provided on the opposite side of the one surface of the insulating plate 92. The relay substrate 90 thus has a structure in which the negative-electrode conductive plate 93, the insulating plate 92, and the positive-electrode conductive plate 91 are stacked in this order from the lower side (from the heat sink 81 side).

### Insulating plate

As illustrated in FIG. 16, the insulating plate 92 extends in the aligned direction of the three semiconductor devices 1 (1u, 1v, 1w) (in the Y direction) in the planar view, and has an oblong planar shape. The insulating plate 92 isolates the positive-electrode conductive plate 91 and the negative-electrode conductive plate 93 from each other.

### Positive-Electrode Conductive Plate

As illustrated in FIGS. 16 and 17, the positive-electrode conductive plate 91 includes a main part 91a fixed to one surface of the insulating plate 92 and extending in the aligned direction of the three semiconductor devices 1 (1u, 1v, 1w) (in the Y direction), and three branch parts 91b extending from the main part 91a in the X direction, aligned in the Y direction at predetermined intervals, and superposed on the respective first conductive pads 41a (the positive-electrode terminals P) of the three semiconductor devices 1 (1u, 1v, 1w) independently of each other.

As illustrated in FIG. 17, the three branch parts 91b each have a gull-wing shape, and a height toward the main part 91a and a height toward a tip end on the opposite side of the main part 91a are offset in the thickness direction of the resin sealing body 50 (in the Z direction). The tip end of the branch part 91b on the opposite side of the main part 91a corresponding to the semiconductor device 1 (1u) illustrated in FIG. 17 is bonded to the top surface 41a₁ of the first conductive pad 41a through the bonding opening 51a of the resin sealing body 50 via conductive bonding material (such as solder material) so as to be electrically and mechanically connected to the first conductive pad 41a.

Although not illustrated in detail, the tip end of the branch part 91b on the opposite side of the main part 91a corresponding to each of the other two semiconductor devices 1 (1v and 1w) is also bonded to the top surface 41a₁ of the first conductive pad 41a through the bonding opening 51a of the resin sealing body 50 via conductive bonding material (such as solder material) so as to be electrically and mechanically connected to the first conductive pad 41a.

### Negative-Electrode Conductive Plate

As illustrated in FIGS. 16 and 18, the negative-electrode conductive plate 93 includes a main part 93a fixed to the other surface opposite to the one surface of the insulating plate 92 and extending in the aligned direction of the three semiconductor devices 1 (1u, 1v, 1w) (in the Y direction), and three branch parts 93b extending from the main part 93a in the X direction, aligned in the Y direction at predetermined intervals, and superposed on the respective second conductive pads 41b (the negative-electrode terminals N) of the three semiconductor devices 1 (1u, 1v, 1w) independently of each other.

As illustrated in FIG. 18, the three branch parts 93b each have a gull-wing shape, and a height toward the main part 93a and a height toward a tip end on the opposite side of the main part 93a are offset in the thickness direction of the resin sealing body 50 (in the Z direction). The tip end of the branch part 93b on the opposite side of the main part 93a corresponding to the semiconductor device 1 (1u) illustrated in FIG. 18 is bonded to the top surface 41b₁ of the second conductive pad 41b through the bonding opening 51b of the resin sealing body 50 via conductive bonding material (such as solder material) so as to be electrically and mechanically connected to the second conductive pad 41b.

Although not illustrated in detail, the tip end of the branch part 93b on the opposite side of the main part 93a corresponding to each of the other two semiconductor devices 1 (1v and 1w) is also bonded to the top surfaces 41b₁ of the second conductive pads 41b through the bonding opening 51b of the resin sealing body 50 via conductive bonding material (such as solder material) so as to be electrically and mechanically connected to the second conductive pad 41b.

### Positions of Branch Parts

As illustrated in FIG. 16, the three branch parts 91b of the positive-electrode conductive plate 91 are arranged at the same intervals as the three branch parts 93b of the negative-electrode conductive plate 93. The three branch parts 91b of the positive-electrode conductive plate 91 are offset with respect to the three branch parts 93b of the negative-electrode conductive plate 93 in the Y direction in the planar view. The offset level is the same, in terms of a design value, as the separated distance between the first conductive pad 41a and the second conductive pad 41b of the semiconductor device 1 in the planar view.

### Material of Relay Conductive Plate

The insulating plate 92 as used herein can be a ceramic substrate having high dielectric strength.

The positive-electrode conductive plate 91 and the negative-electrode conductive plate 93 each can include an iron (Fe)-nickel (Ni) alloy having high electric and heat conductive properties, for example.

### OTHER STRUCTURES

As illustrated in FIG. 15, the positive-electrode conductive plate 91 is electrically connected to a positive-electrode terminal 85P of the capacitor unit 85. The positive-electrode terminal 85P of the capacitor unit 85 is electrically connected to a positive-electrode power-supply line 86P. The negative-electrode conductive plate 93 is electrically connected to a negative-electrode terminal 85N of the capacitor unit 85. The negative-electrode terminal 85N of the capacitor unit 85 is electrically connected to a negative-electrode power-supply line 86N. A potential applied to the positive-electrode power-supply line 86P is supplied to the positive-electrode terminal 85P of the capacitor unit 85 and the respective first conductive pads 41a of the three semiconductor devices 1 (1u, 1v, and 1w), and a potential applied to the negative-electrode power-supply line 86N is supplied to the negative-electrode terminal 85N of the capacitor unit 85 and the respective second conductive pads 41b of the three semiconductor devices 1 (1u, 1v, and 1w).

As described above, the relay substrate 90 includes the insulating plate 92, the positive-electrode conductive plate 91 provided on one surface of the insulating plate 92 and electrically connected to the positive-electrode terminal 85P of the capacitor unit 85 and the respective first conductive pads 41a of the three semiconductor devices 1 (1u, 1v, and 1w), and the negative-electrode conductive plate 93 provided on the opposite side of the one surface of the insulating plate 92 and electrically connected to the negative-electrode terminal 85N of the capacitor unit 85 and the respective second conductive pads 41b of the three semiconductor devices 1 (1u, 1v, and 1w).

The power conversion apparatus 80 according to the first embodiment has a configuration in which gate signals (control signals) output from a gate drive circuit are input to first and second control terminals G1 and G2 of each of the three semiconductor devices 1 (1u, 1v, and 1w) illustrated in FIG. 15, so as to lead each of a U-phase motor drive current, a V-phase motor drive current, and a W-phase motor drive current to flow from the respective output terminals O of the respective semiconductor devices 1 (1u, 1v, and 1w) toward a motor winding of the three-phase dielectric motor 89.

### MAIN EFFECTS ACCORDING TO FIRST EMBODIMENT

Main effects according to the first embodiment are described below.

The effects regarding a creepage distance are described first.

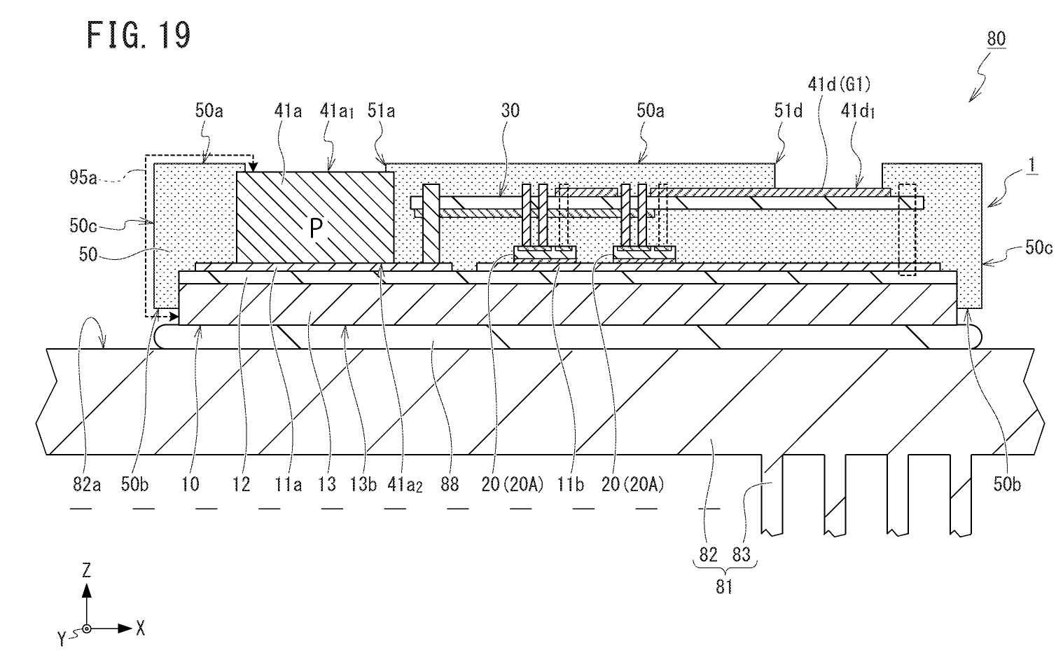

FIG. 19 is a view illustrating the semiconductor device 1 according to the first embodiment, showing a creepage distance 95a when the cooling plate 13 projects downward from the bottom surface 50b of the resin sealing body 50.

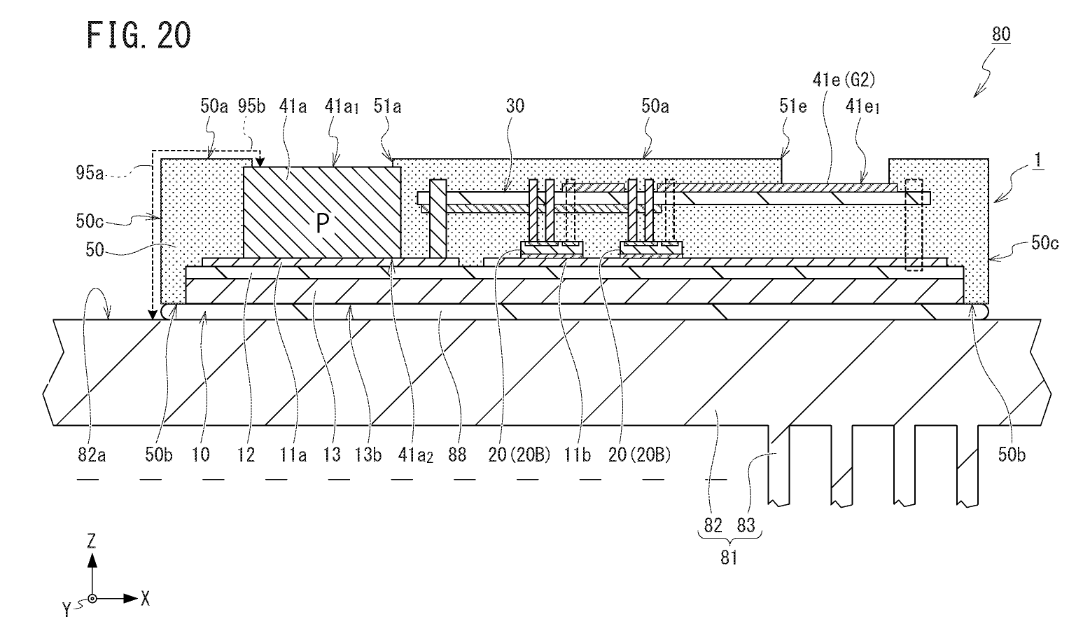

FIG. 20 is a view illustrating the semiconductor device 1 according to the first embodiment, showing a creepage distance 95b when the bottom surface 50b of the resin sealing body 50 and the bottom surface 13b of the cooling plate 13 are level with each other.

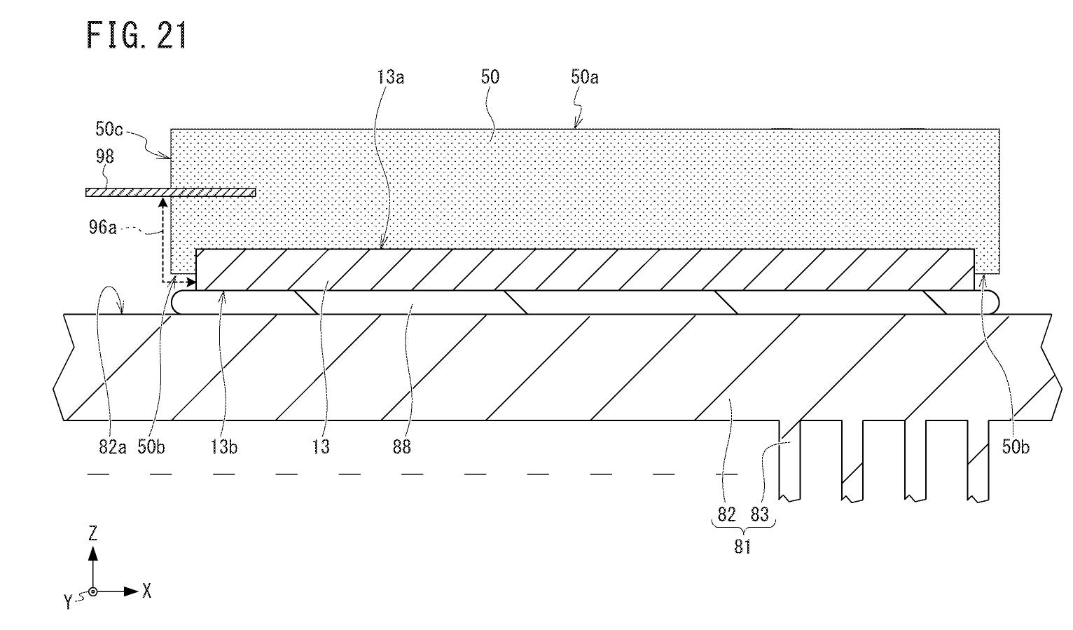

FIG. 21 is a view illustrating a conventional semiconductor device of a referential example, showing a creepage distance 96a when a lead 98 serving as an external terminal projects from the side surface 50c of the resin sealing body 50, and the cooling plate 13 projects downward from the bottom surface 50b of the resin sealing body 50.

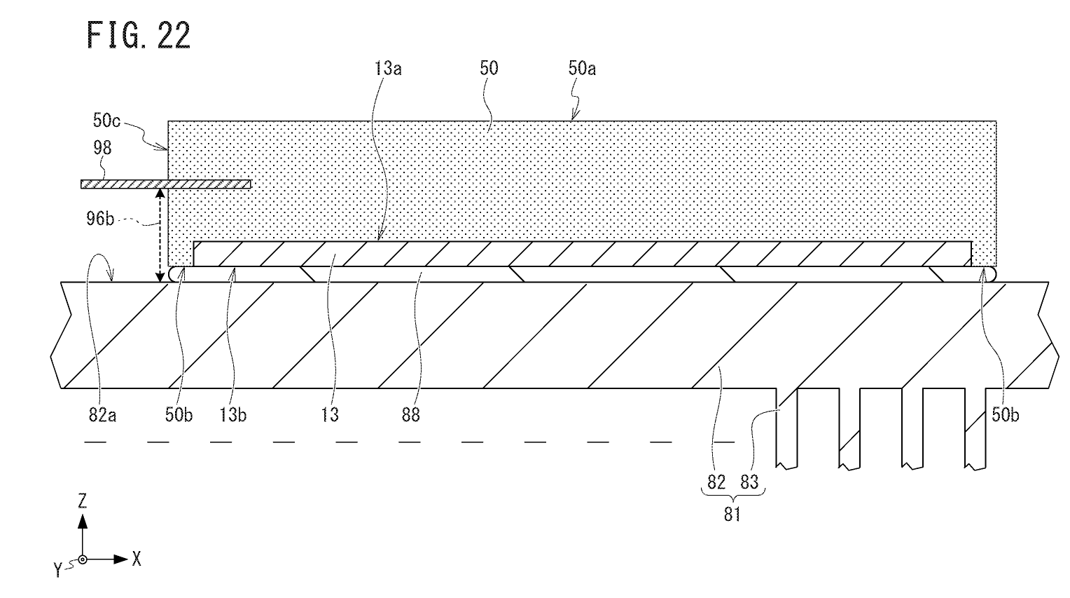

FIG. 22 is a view illustrating the conventional semiconductor device of the referential example, showing a creepage distance 96b when the lead 98 serving as an external terminal projects from the side surface 50c of the resin sealing body 50, and the bottom surface 50b of the resin sealing body 50 and the bottom surface 13b of the cooling plate 13 are level with each other.

The power conversion apparatus 80 typically has a structure in which the cooling plate 13 of the semiconductor device 1 is attached to the component-mount surface 82a of the heat sink 81 with the heat-conductive material layer 88 interposed. In the case in which the cooling plate 13 projects from the bottom surface 50b of the resin sealing body 50, as illustrated in FIG. 19, it is necessary to ensure a creepage distance along the surface of the resin sealing body 50 between the external terminal (the first conductive pad 41a in FIG. 19) of the semiconductor device and the cooling plate 13 in order to increase dielectric strength, since the power conversion apparatus 80 typically uses high voltage. In the case in which the bottom surface 50b of the resin sealing body 50 and the bottom surface 13b of the cooling plate 13 are level with each other, as illustrated in FIG. 20, it is necessary to ensure a creepage distance along the surface of the resin sealing body 50 between the external terminal (the first conductive pad 41a in FIG. 20) of the semiconductor device and the heat sink 81 in order to increase dielectric strength.

As compared with this, the conventional semiconductor device of the referential example illustrated in FIG. 21 has the structure in which the lead 98 serving as an external terminal projects from the side surface 50c of the resin sealing body 50. In the case in which the cooling plate 13 projects from the bottom surface 50b of the resin sealing body 50, as illustrated in FIG. 21, such a structure decreases the creepage distance 96a along the surface of the resin sealing body 50 between the external terminal (the lead 98) and the cooling plate 13, which impedes the provision of the creepage distance 96a sufficient for electric power to be required. The creepage distance 96a in this case is the shortest distance along the side surface 50c and the bottom surface 50b of the resin sealing body 50 between the lead 98 and the cooling plate 13.

In the case in which the bottom surface 50b of the resin sealing body 50 and the bottom surface 13b of the cooling plate 13 are level with each other, as illustrated in FIG. 22, the conventional structure also decreases the creepage distance 96b along the surface of the resin sealing body 50 between the external terminal (the lead 98) and the heat sink 81, which impedes the provision of the creepage distance 96b sufficient for electric power to be required. The creepage distance 96b in this case is the shortest distance along the side surface 50c of the resin sealing body 50 between the lead 98 and the heat sink 81.

In contrast, the semiconductor device 1 according to the first embodiment has the structure, as illustrated in FIG. 19, in which the first conductive pad 41a serving as an external terminal is exposed to the bonding opening 51a of the top surface 50a of the resin sealing body 50. In the case in which the cooling plate 13 projects from the bottom surface 50b of the resin sealing body 50, the creepage distance 95a along the surface of the resin sealing body 50 between the external terminal (the first conductive pad 41a) and the cooling plate 13 as illustrated in FIG. 19 is longer than the creepage distance 96a in the conventional case as illustrated in FIG. 21, which facilitates the provision of the creepage distance 95a sufficient for electric power to be required. The creepage distance 95a in this case is the shortest distance along the inner-wall surface of the bonding opening 51a, the top surface 50a, the side surface 50c, and the bottom surface 50b of the resin sealing body 50 mainly between the first conductive pad 41a and the cooling plate 13.

Similarly, in the case in which the bottom surface 50b of the resin sealing body 50 and the bottom surface 13b of the cooling plate 13 are level with each other, as illustrated in FIG. 20, the creepage distance 95b along the surface of the resin sealing body 50 between the external terminal (the first conductive pad 41a) and the heat sink 81 as illustrated in FIG. 20 is longer than the creepage distance 96b in the conventional case as illustrated in FIG. 22, which facilitates the provision of the creepage distance 95a sufficient for electric power to be required. The creepage distance 95b in this case is the shortest distance along the inner-wall surface of the bonding opening 51a, the top surface 50a, and the side surface 50c of the resin sealing body 50 mainly between the first conductive pad 41a and the heat sink 81.

The semiconductor device 1 according to the first embodiment as described above has the configuration that can facilitate the provision of the sufficient creepage distance 95a in the case in which the cooling plate 13 projects from the bottom surface 50b of the resin sealing body 50 and also facilitate the provision of the sufficient creepage distance 95b in the case in which the bottom surface 50b of the resin sealing body 50 and the bottom surface 13b of the cooling plate 13 are level with each other, so as to increase the dielectric strength of the semiconductor device 1 without the thickness or size of the resin sealing body 50 increased.

The configuration of the semiconductor device 1 according to the first embodiment thus can enhance the dielectric strength while avoiding an increase in size of a package.

This configuration that can improve the dielectric strength while avoiding an increase in size of the package of the semiconductor device 1 as described above, can increase a package density of the semiconductor device 1 in the power conversion apparatus 80 and improve the reliability of the power conversion apparatus 80 accordingly.

While the explanations are made above with regard to the first conductive pad 41a serving as an external terminal, the semiconductor device 1 according to the first embodiment has the configuration of including the second to fifth conductive pads 41b, 41c, 41d, and 41e each serving as an external terminal, in addition to the first conductive pad 41a, which are also respectively exposed to the bonding openings 51b, 51c, 51d, and 51e of the top surface 50a of the resin sealing body 50.

The creepage distance between the respective external terminals (the second to fifth conductive pads 41b, 41c, 41d, and 41e) and the cooling plate 13 or the creepage distance between the respective external terminals (the second to fifth conductive pads 41b, 41c, 41d, and 41e) and the heat sink 81 is also longer than the creepage distance 96a or 96b in the conventional case, so as to facilitate the provision of the creepage distance sufficient for electric power to be required, and enhance the dielectric strength of the semiconductor device 1 without the thickness or planar size of the resin sealing body 50 increased.

Since it is particularly necessary to ensure the sufficient creepage distance between the first conductive pad 41a (the positive-electrode terminal P) or the second conductive pad 41b (the negative-electrode terminal N) serving as an external terminal to which electric power is applied and the cooling plate 13 or the heat sink 81, and also particularly necessary to ensure the sufficient creepage distance between the third conductive pad 41c (the output terminal O) serving as an external terminal for outputting current and the cooling plate 13 or the heat sink 81, at least the first to third conductive pads 41a to 41c are preferably arranged toward the top surface 50a of the resin sealing body 50 so as to be exposed to the bonding openings 51a to 51c.

In addition, since a difference in potential between the first conductive pad 41a and the heat sink 81 is large, at least the first conductive pad 41a is preferably arranged toward the top surface 50a of the resin sealing body 50 so as to be exposed to the bonding opening 51a.

Conventional semiconductor devices are also known that have a package structure in which lead pins serving as external terminals project from a top surface of a resin sealing body. Such a package structure is required to provide pin housing parts in a molding metal die so as to house the lead pins during a step of forming the resin sealing body by transfer molding suitable for mass production. This structure inevitably requires a means for avoiding entrance of resin into the pin housing parts, which complicates the structure of the molding metal die to be used and could lead to an increase in manufacturing cost or a reduction in yield rate.

In contrast, the resin sealing body 50 in the first embodiment has the package structure in which the respective top surfaces 41a₁, 41b₁, 41c₁, 41d₁, and 41e₁ of the first, second, third, fourth, and fifth conductive pads 41a, 41b, 41c, 41d, and 41e are exposed outward through the top surface 50a of the resin sealing body 50. In addition, the respective top surfaces 41a₁, 41b₁, 41c₁, 41d₁, and 41e₁ of the first, second, third, fourth, and fifth conductive pads 41a, 41b, 41c, 41d, and 41e are evenly flat. This package structure can use the molding metal die 70 provided with the first projection 72a, the second projection, the third projection 72c, the fourth projection, and the fifth projection in the recess 72 of the upper die 71, as illustrated in FIG. 12, so as to easily form the resin sealing body 50 by transfer molding suitable for mass production in the manufacture of the semiconductor device 1. The first projection 72a, the second projection, the third projection 72c, the fourth projection, and the fifth projection can be provided in the molding metal die 70 easily, as compared with the case in which the pin housing parts for housing lead pins are provided in the molding metal die.

The structure of the semiconductor device 1 according to the first embodiment thus can achieve a reduction in manufacturing cost and improve the yield rate more reliably than the conventional package structure in which the lead pins serving as external terminals project from the top surface of the resin sealing body.

The respective bottom surfaces 41a₂, 41b₂, and 41c₂ of the first, second, and third conductive pads 41a, 41b, and 41c in the first embodiment are directly fixed to the insulated circuit substrate 10. This structure can enhance the press-fit strength (the tight contact) between the top surface 41a₁ of the first conductive pad 41a and the top surface of the first projection 72a of the upper die 71, the press-fit strength (the tight contact) between the top surface 41c₁ of the third conductive pad 41c and the top surface of the third projection 72c of the upper die 71, and the press-fit strength (the tight contact) between the top surface 41b₁ of the second conductive pad 41b and the top surface of the second projection of the upper die 71 when the assembly structure body 60 is placed inside the cavity 75 defined by the upper die 71 and the lower die 73 of the molding metal die 70 so as to be clamped together, as illustrated in FIG. 13, during the process of manufacturing the semiconductor device 1. This structure can also avoid the entrance of the resin to the interface between the top surface 41a₁ of the first conductive pad 41a and the top surface of the first projection 72a of the upper die 71, the entrance of the resin to the interface between the top surface 41c₁ of the third conductive pad 41c and the top surface of the third projection 72c of the upper die 71, and the entrance of the resin to the interface between the top surface 41b₁ of the second conductive pad 41b and the top surface of the second projection of the upper die 71 when the resin is injected with pressure into the cavity 75 of the molding metal die 70 so as to form the resin sealing body 50, as illustrated in FIG. 14.

The configuration of the semiconductor device 1 according to the first embodiment as described above thus can improve the yield rate.

The fourth conductive pad 41d and the fifth conductive pad 41e in the first embodiment are provided on the wired substrate 30. The wired substrate 30 is fixed to the insulated circuit substrate 10 via the first and second conductive members 35 and 36, the conductive pins 37a, 37b, 37d, and 37e, and the four positioning pins 38a, 38b, 38c, and 38d. This structure can enhance the press-fit strength (the tight contact) between the top surface 41d₁ of the fourth conductive pad 41d and the top surface of the fourth projection of the upper die 71 and the press-fit strength (the tight contact) between the top surface 41e₁ of the fifth conductive pad 41e and the top surface of the fifth projection of the upper die 71 when the assembly structure body 60 is placed inside the cavity 75 defined by the upper die 71 and the lower die 73 of the molding metal die 70 so as to be clamped together, as illustrated in FIG. 13, during the process of manufacturing the semiconductor device 1. This structure can also avoid the entrance of the resin to the interface between the top surface 41d₁ of the fourth conductive pad 41d and the top surface of the fourth projection of the upper die 71 and the entrance of the resin to the interface between the top surface 41e₁ of the fifth conductive pad 41e and the top surface of the fifth projection of the upper die 71 when the resin is injected with pressure into the cavity 75 of the molding metal die 70 so as to form the resin sealing body 50, as illustrated in FIG. 14. The configuration of the semiconductor device 1 according to the first embodiment as described above thus can improve the yield rate.

The respective middle regions of the top surfaces 41a₁, 41b₁, and 41c_{b} of the first, second, and third conductive pads 41a, 41b, and 41c in the first embodiment are exposed to the outside of the resin sealing body 50 through the first, second, and third bonding openings 51a, 51b, and 51c provided on the top surface 50a of the resin sealing body 50, and the outer edge regions surrounding the respective middle regions of the top surfaces 41a₁, 41b₁, and 41c₁ are covered continuously along the outer circumferences with the resin sealing body 50. Similarly, the respective middle regions of the top surfaces 41d₁ and 41e₁ of the fourth and fifth conductive pads 41d and 41e are exposed to the outside of the resin sealing body 50 through the fourth and fifth bonding openings 51d and 51e provided on the top surface 50a of the resin sealing body 50, and the outer edge regions surrounding the respective middle regions of the top surfaces 41d₁ and 41e₁ are covered continuously along the outer circumferences with the resin sealing body 50. This structure can increase moisture penetration paths at the boundaries between the first, second, third, fourth, and fifth conductive pads 41a, 41b, 41c, 41d, and 41e and the resin of the resin sealing body 50, so as to avoid corrosion inside the semiconductor device 1 to thus improve the reliability of the semiconductor device 1.

The relay substrate 90 in the first embodiment has the structure in which the branch parts 91b of the positive-electrode conductive plate 91 are arranged at the same intervals as the branch parts 93b of the negative-electrode conductive plate 93 in terms of a design value. This structure can use a common conductive member for each of the positive-electrode conductive plate 91 and the negative-electrode conductive plate 93, so as to achieve a reduction in cost regarding the relay substrate 90 and thus achieve a reduction in cost regarding the power conversion apparatus 80 including the relay substrate 90.

The semiconductor device 1 also includes the first and second conductive pads 41a and 41b such that the respective top surfaces 41a₁ and 41b₁are exposed to the bonding openings 51a and 51b provided on the top surface 50a of the resin sealing body 50. This structure can facilitate the connection between the top surface 41a₁ of the first conductive pad 41a and the branch part 91b of the positive-electrode conductive plate 91 and the connection between the top surface 41b₁ of the second conductive pad 41b and the branch part 93b of the negative-electrode conductive plate 93.

### MODIFIED EXAMPLES OF FIRST EMBODIMENT

### Modified Example 1-1

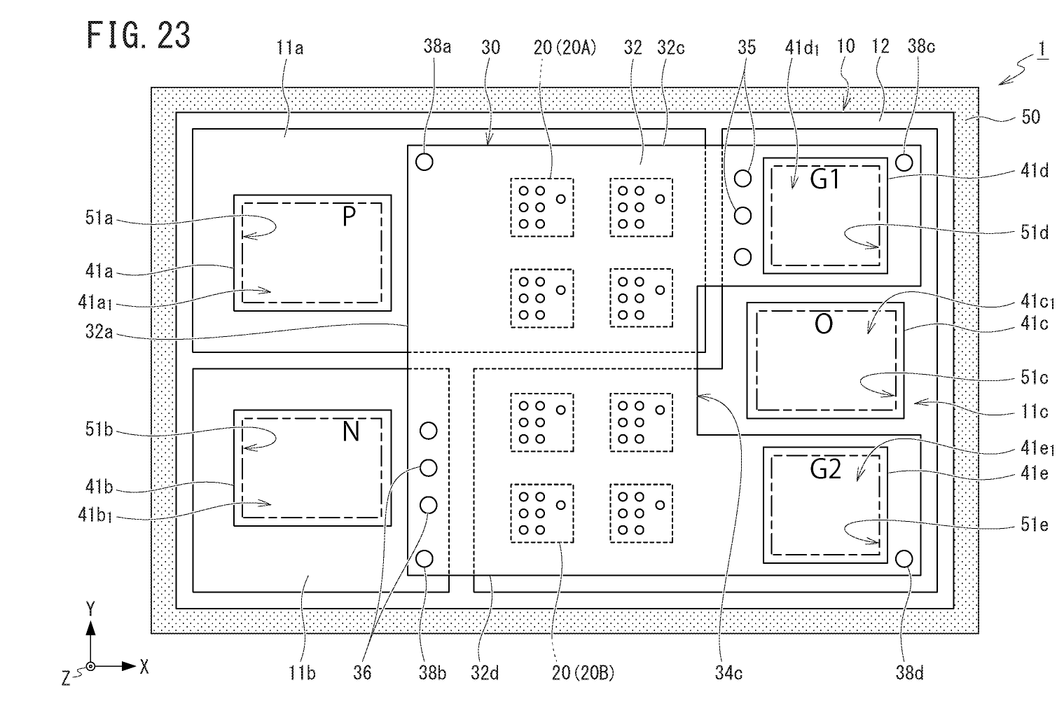

FIG. 23 is a plan view schematically illustrating an inner structure of a semiconductor device of modified example 1-1 according to the first embodiment of the present technology.

The first embodiment 1 described above has the structure in which the recess 34a corresponding to the first conductive pad 41a and the recess 34b corresponding to the second conductive pad 41b are recessed along the short side 32a on one side of the insulating plate 32 included in the wired substrate 30. The first conductive pad 41a extends through the inside of the recess 34a across the wired substrate 30 in the thickness direction (the Z direction), and the second conductive pad 41b extends through the inside of the recess 34b across the wired substrate 30 in the Z direction.

The modified example 1-1 has a structure in which the first and second conductive pads 41a and 41b extends across the wired substrate 30 in the thickness direction (the Z direction) on the outside of the one short side 32a of the insulating plate 32 included in the wired substrate 30 (the insulating plate 32), while the provision of the recesses along the one short side 32a of the wired substrate 30 is eliminated.

The configuration according to the present technology can also be applied to the modified example 1-1, so as to achieve the effects similar to those in the first embodiment as described above.

### Modified Example 1-2

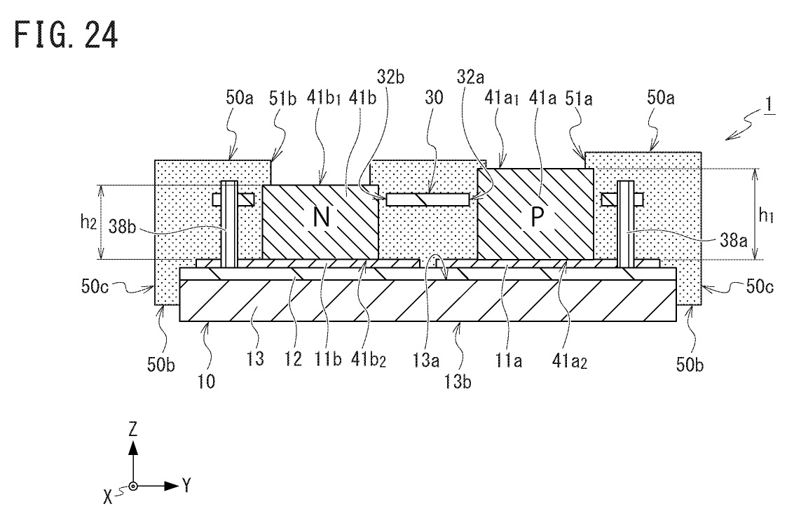

FIG. 24 is a cross-sectional view schematically illustrating a vertical cross-sectional structure of a semiconductor device of modified example 1-2 according to the first embodiment of the present technology.

As illustrated in FIG. 9, the first embodiment described above has the structure in which the heights h₁ and h₂ of the top surfaces 41a₁ and 41b₁ of the first conductive pad 41a and the second conductive pad 41b from the insulated circuit substrate 10 are common to each other in terms of a design value.

As illustrated in FIG. 24, the modified example 1-2 has a structure in which the heights h₁ and h₂of the top surfaces 41a₁ and 41b₁ of the first conductive pad 41a and the second conductive pad 41b from the insulated circuit substrate 10 are different from each other. While this modified example is illustrated with the case in which the height h₁of the top surfaces 41a₁ of the first conductive pad 41a is greater than the height h₂ of the top surfaces 41b₁ of the second conductive pad 41b, the height h₂ of the top surfaces 41b₁ of the second conductive pad 41b may be greater than the height h₁of the top surfaces 41a₁ of the first conductive pad 41a instead.

The configuration according to the present technology can also be applied to the modified example 1-2, so as to achieve the effects similar to those in the first embodiment as described above.

### OTHER EMBODIMENTS

The first embodiment is illustrated above with the semiconductor device of package type (2-in-1 type) including two elements, used for the power conversion apparatus. The present technology is, however, not limited to the 2-in-1 semiconductor device, but can also be applied to a semiconductor device of package type including one element (1-in-1 type) or a semiconductor device of package type including more than two elements.

The first embodiment is also illustrated above with the vertical MISFET as a transistor mounted on the respective semiconductor chips 20 (20A and 20B), but the present technology can also be applied to a case of using an IGBT as a transistor mounted on the respective semiconductor chips 20.

While the present technology has been described in detail above with reference to the embodiment and the modified examples, it should be noted that the present technology is not intended to be limited to those, and it will be apparent to those skilled in the art that various modifications may be made without departing from the scope of the invention.

What is claimed is:

1. A semiconductor device comprising:
an insulated circuit substrate including a first conductive plate, a second conductive plate, and a third conductive plate on one surface, and a cooling plate on another surface opposite to the one surface;
a first semiconductor chip having a main surface and a rear surface opposed to each other each provided with an electrode, the electrode of the rear surface being connected to the first conductive plate;
a second semiconductor chip having a main surface and a rear surface opposed to each other each provided with an electrode, the electrode of the rear surface being connected to the third conductive plate;
a wired substrate provided toward the one surface of the insulated circuit substrate so as to be arranged separately from the respective first and second semiconductor chips, and including a first wiring part electrically connected to the electrode of the main surface of the first semiconductor chip and a second wiring part electrically connected to the electrode of the main surface of the second semiconductor chip;
a first conductive pad provided toward the one surface of the insulated circuit substrate so as to be connected to the first conductive plate, and having a flat top surface;
a second conductive pad provided toward the one surface of the insulated circuit substrate so as to be connected to the second conductive plate, and having a flat top surface;
a third conductive pad provided toward the one surface of the insulated circuit substrate so as to be connected to the third conductive plate, and having a flat top surface;
a first conductive member connected to each of the first wiring part and the third conductive plate;
a second conductive member connected to each of the second wiring part and the second conductive plate; and
a resin sealing body having a first surface and a second surface opposed to each other to seal the insulated circuit substrate, the first and second semiconductor chips, and the wired substrate in a state in which the respective top surfaces of the first, second, and third conductive pads are exposed outward through the first surface, and the cooling plate is exposed outward through the second surface.

2. The semiconductor device of claim 1, wherein the respective top surfaces of the first, second, and third conductive pads are positioned closer to the first surface of the resin sealing body than the wired substrate.

3. The semiconductor device of claim 1, wherein the first, second, and third conductive pads each have a greater thickness than the wired substrate.

4. The semiconductor device of claim 1, wherein the first, second, and third conductive pads are each directly fixed to the insulated circuit substrate.

5. The semiconductor device of claim 1, wherein the respective top surfaces of the first, second, and third conductive pads have a middle region exposed outward from the resin sealing body, and an outer edge region surrounding the middle region and covered with the resin sealing body.

6. The semiconductor device of claim 1, wherein the first and second wiring parts are stacked on the insulating plate.

7. The semiconductor device of claim 1, wherein heights of the respective top surfaces of the first, second, and third conductive pads from the insulated circuit substrate are common to each other.

8. The semiconductor device of claim 1, wherein heights of the respective top surfaces of the first and second conductive pads from the insulated circuit substrate are different from each other.

9. The semiconductor device of claim 1, further comprising a positioning member for aligning the insulated circuit substrate and the wired substrate in relative position,
wherein the wired substrate is supported on the insulated circuit substrate via the positioning member and the respective first and second conductive members.

10. An electronic apparatus comprising a heat sink and a plurality of semiconductor devices mounted on the heat sink,
wherein the respective semiconductor devices comprise:
an insulated circuit substrate including a first conductive plate, a second conductive plate, and a third conductive plate on one surface, and a cooling plate on another surface opposite to the one surface;
a first semiconductor chip having a main surface and a rear surface opposed to each other each provided with an electrode, the electrode of the rear surface being connected to the first conductive plate;
a second semiconductor chip having a main surface and a rear surface opposed to each other each provided with an electrode, the electrode of the rear surface being connected to the third conductive plate;
a wired substrate provided toward the one surface of the insulated circuit substrate so as to be arranged separately from the respective first and second semiconductor chips, and including a first wiring part electrically connected to the electrode of the main surface of the first semiconductor chip and a second wiring part electrically connected to the electrode of the main surface of the second semiconductor chip;
a first conductive pad provided toward the one surface of the insulated circuit substrate so as to be connected to the first conductive plate, and having a flat top surface;
a second conductive pad provided toward the one surface of the insulated circuit substrate so as to be connected to the second conductive plate, and having a flat top surface;
a third conductive pad provided toward the one surface of the insulated circuit substrate so as to be connected to the third conductive plate, and having a flat top surface;
a first conductive member connected to each of the first wiring part and the third conductive plate;
a second conductive member connected to each of the second wiring part and the second conductive plate; and
a resin sealing body having a first surface and a second surface opposed to each other to seal the insulated circuit substrate, the first and second semiconductor chips, and the wired substrate in a state in which the respective top surfaces of the first, second, and third conductive pads are exposed outward through the first surface, and the cooling plate is exposed outward through the second surface.

11. The electronic apparatus of claim 10, wherein the cooling plate on one side on an opposite side of a surface toward the resin sealing body in the respective semiconductor devices is connected to the heat sink with a heat-conductive material layer interposed.

12. The electronic apparatus of claim 10, further comprising:
a capacitor unit including a positive-electrode terminal and a negative-electrode terminal; and
a relay substrate electrically connecting the respective semiconductor device and the capacitor unit to each other,
wherein the relay substrate includes an insulating plate, a positive-electrode conductive plate provided on one surface of the insulating plate and electrically connected to each of the positive-electrode terminal of the capacitor unit and the first conductive pad of the respective semiconductor devices, and a negative-electrode conductive plate provided on an opposite side of the one surface of the insulating plate and electrically connected to each of the negative-electrode terminal of the capacitor unit and the second conductive pad of the respective semiconductor devices.
